(19) United States
(12) Patent Application Publication
(10) Pub. No.: US 2021/0359237 A1
(43) Pub. Date: Nov. 18, 2021

(54) SOLAR HEAT GAIN COEFFICIENT IMPROVEMENT BY INCORPORATING NIR ABSORBERS

(71) Applicant: Ubiquitous Energy, Inc., Redwood City, CA (US)

(72) Inventors: Richa Pandey, Sunnyvale, CA (US); Matthew E. Sykes, Redwood City, CA (US); John A. Love, Mountain View, CA (US); Miles C. Barr, Redwood City, CA (US)

(73) Assignee: Ubiquitous Energy, Inc., Redwood City, CA (US)

(21) Appl. No.: 17/308,917

(22) Filed: May 5, 2021

Related U.S. Application Data
(60) Provisional application No. 63/025,840, filed on May 15, 2020.

(51) Int. Cl. H01L 51/42; H01L 51/44; H01L 51/00

(52) U.S. Cl. CPC H01L 51/4213; H01L 51/4226; H01L 51/4233; H01L 51/4253; H01L 51/0071; H01L 51/0077; H01L 51/0061; H01L 51/442; H01L 51/0068; H01L 51/447

(57) ABSTRACT

A visibly transparent photovoltaic device includes a visibly transparent substrate, a first visibly transparent electrode on the visibly transparent substrate, a second electrode, a visibly transparent photoactive layer between the first visibly transparent electrode and the second electrode and configured to convert at least one of near-infrared light or ultraviolet light into photocurrent, and a near-infrared absorbing material layer configured to absorb the near-infrared light and transmit visible light.

### CROSS-REFERENCES TO RELATED APPLICATIONS

This application claims the benefit of priority to U.S. Provisional Patent Application No. 63/025,840 filed May 15, 2020, entitled “SOLAR HEAT GAIN COEFFICIENT IMPROVEMENT BY INCORPORATING NIR ABSORBERS”, the entire content of which is incorporated herein by reference for all purposes.

### BACKGROUND OF THE INVENTION

Low-cost, visibly transparent or semitransparent photovoltaic (PV) devices may be integrated into window panes in homes, skyscrapers, automobiles, and other structures, to significantly increase the surface area for solar energy harvesting, while illuminating the interior of structures with visible light. For example, building-integrated photovoltaic cells can be used to convert solar energy irradiated onto buildings into electrical energy that can be used or stored at the building or can be fed back to the power grid, and to reduce heating of the building by solar energy (e.g., infrared light). Traditional PV cells may have opacity and aesthetic issues and may not be suitable for use in some window panes.

In addition, windows may gain or lose heat through direct conduction through the glass, glazing, and frames, as well as the radiation of heat (e.g., from the sun) through the window. It is often desirable that window panes integrating PV cells have certain thermal energy performance to regulate the heat gain or loss based on the condition of the ambient environment, such as the climate, orientation, external shading, and the like.

### SUMMARY OF THE INVENTION

Techniques disclosed herein relate generally to window coatings. More particularly, and without limitation, disclosed herein are materials and devices that can be integrated into windows and selectively absorb near-infrared light and transmit visible light. The materials and devices may be integrated into transparent or semitransparent photovoltaic devices used in windows or can be coated on regular windows. The materials and devices can help to reduce heat transmission and improve visible light transmission through the windows. Various inventive embodiments are described herein, including materials, combinations of materials, devices, systems, modules, methods, and the like.

A summary of the various embodiments of the invention is provided below as a list of examples. As used below, any reference to a series of examples is to be understood as a reference to each of those examples disjunctively (e.g., “Examples 1-4” is to be understood as “Examples 1, 2, 3, or 4”).

Example 1 is a visibly transparent photovoltaic device comprising: a visibly transparent substrate; a first visibly transparent electrode on the visibly transparent substrate; a second electrode; a visibly transparent photoactive layer between the first visibly transparent electrode and the second electrode, the visibly transparent photoactive layer configured to convert at least one of near-infrared light or ultraviolet light into photocurrent; and a near-infrared absorbing material layer configured to absorb the near-infrared light and transmit visible light.

Example 2 is the visibly transparent photovoltaic device of example(s) 1, wherein the near-infrared absorbing material layer is characterized by a peak extinction coefficient at a wavelength longer than 650 nm.

Example 3 is the visibly transparent photovoltaic device of example(s) 2, wherein the peak extinction coefficient is greater than 0.4.

Example 4 is the visibly transparent photovoltaic device of example(s) 2-3, wherein the near-infrared absorbing material layer includes SnNcCl2, SnNc, or BBT.

Example 5 is the visibly transparent photovoltaic device of example(s) 1-4, wherein the near-infrared absorbing material layer includes an antireflection layer for the visible light.

Example 6 is the visibly transparent photovoltaic device of example(s) 5, wherein the antireflection layer is on the visibly transparent substrate or the second electrode.

Example 7 is the visibly transparent photovoltaic device of example(s) 1-6, wherein the near-infrared absorbing material layer is in the visibly transparent photoactive layer.

Example 8 is the visibly transparent photovoltaic device of example(s) 1-6, further comprising a hole transport layer, wherein the near-infrared absorbing material layer is in the hole transport layer.

Example 9 is the visibly transparent photovoltaic device of example(s) 8, wherein the hole transport layer includes at least one of MoO3, WO3, NiOx, ITO, or V2O5.

Example 10 is the visibly transparent photovoltaic device of example(s) 1, further comprising an electron transport layer, wherein the near-infrared absorbing material layer is in the electron transport layer.

Example 11 is the visibly transparent photovoltaic device of example(s) 10, wherein the electron transport layer includes at least one of ZnO, In2O3, SnO2, TiO2, AZO, FTO, Al:MoO3, or BaSnO3.

Example 12 is the visibly transparent photovoltaic device of example(s) 1, further comprising an antireflection layer, a hole transport layer, and an electron transport layer, wherein the near-infrared absorbing material layer is in at least one of the antireflection layer, the hole transport layer, the electron transport layer, or the visibly transparent photoactive layer.

Example 13 is the visibly transparent photovoltaic device of example(s) 1-12, wherein the second electrode is configured to at least partially reflect the near-infrared light.

Example 14 is the visibly transparent photovoltaic device of example(s) 13, wherein the second electrode includes a silver layer characterized by a thickness equal to or less than 20 nm.

Example 15 is the visibly transparent photovoltaic device of example(s) 1-14, wherein the near-infrared absorbing material layer is characterized by a thickness less than 60 nm.

Example 16 is the visibly transparent photovoltaic device of example(s) 1-15, wherein the visibly transparent photovoltaic device is characterized by an average visible transmittance equal to or greater than 0.45.

Example 17 is the visibly transparent photovoltaic device of example(s) 1-16, wherein the visibly transparent photovoltaic device is characterized by a selectivity equal to or greater than 1.5.

Example 18 is the visibly transparent photovoltaic device of example(s) 1-17, wherein the visibly transparent photoactive layer includes a donor material and an acceptor material.

Example 19 is the visibly transparent photovoltaic device of example(s) 1-18, wherein the visibly transparent photoactive layer includes a bulk heterojunction.

Example 20 is a window panel comprising: a visibly transparent substrate; a first visibly transparent dielectric layer on the visibly transparent substrate; a near-infrared reflection layer on the first visibly transparent dielectric layer and configured to at least partially reflect near-infrared light; and a second visibly transparent dielectric layer on the near-infrared reflection layer, wherein at least one of the first visibly transparent dielectric layer or the second visibly transparent dielectric layer includes a near-infrared absorbing material configured to absorb the near-infrared light and transmit visible light.

Example 21 is the window panel of example(s) 20, wherein the near-infrared absorbing material includes at least one of SnNcCl2, SnNc, or BBT.

Example 22 is the window panel of example(s) 20-21, wherein the near-infrared reflection layer includes a silver layer.

Numerous benefits are achieved using techniques described in the present disclosure over conventional techniques. Embodiments in the present disclosure provide combinations of materials and devices for absorbing near-infrared radiation to reduce solar heat gain and improve the selectivity in transparent photovoltaics and low-emissivity window coatings. Advantageously, these optical characteristics represent an alternative pathway to enhance the thermal performance of transparent photovoltaics and low-emissivity coatings that is complementary to traditional approaches while still allowing for high average visible light transmittance.

These and other embodiments and aspects of the invention along with many of its advantages and features are described in more detail in conjunction with the text below and attached figures.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified diagram illustrating an example of a visibly transparent photovoltaic device according to certain embodiments.

FIGS. 2A-2E illustrate various configurations of photoactive layer(s) in visibly transparent photovoltaic devices according to certain embodiments.

FIG. 3 is simplified plot illustrating the solar spectrum, human eye sensitivity, and the absorption spectrum of an example of a transparent photovoltaic device as a function of light wavelength.

FIGS. 4A-4D illustrate examples of insulated glass units (IGUs) for windows according to certain embodiments.

FIG. 5 illustrates an example of a visibly transparent photovoltaic device including multiple layers that can include a near-infrared (NIR) absorbing material according to certain embodiments.

FIG. 6 illustrates extinction coefficients of examples of materials that may be used in the coating layers in IGUs according to certain embodiments.

FIG. 7A illustrates examples of transparent photovoltaic (TPV) devices each including HAT-CN as a transparent antireflection (AR) layer having a different respective thickness according to certain embodiments.

FIG. 7B illustrates simulated performance of the examples of TPV devices shown in FIG. 7A.

FIG. 8A illustrates examples of TPV devices each including SnNcCl₂ as a selective NIR absorbing material in an AR layer having a different respective thickness according to certain embodiments.

FIG. 8B illustrates simulated performance of the examples of TPV devices shown in FIG. 8A.

FIG. 9A illustrates examples of TPV devices each including SnNc as a selective NIR absorbing material in an AR layer having a different respective thickness according to certain embodiments.

FIG. 9B illustrates simulated performance of the examples of TPV devices shown in FIG. 9A.

FIG. 10A illustrates examples of TPV devices each including BBT as a selective NIR absorbing material in an AR layer having a different respective thickness according to certain embodiments.

FIG. 10B illustrates simulated performance of the examples of TPV devices shown in FIG. 10A.

FIG. 11A illustrates examples of TPV devices each including NiDT as a selective NIR absorbing material in an AR layer having a different respective thickness according to certain embodiments.

FIG. 11B illustrates simulated performance of the examples of TPV devices shown in FIG. 11A.

FIG. 12A illustrates examples of TPV devices each including QQT as a selective NIR absorbing material in an AR layer having a different respective thickness according to certain embodiments.

FIG. 12B illustrates simulated performance of the examples of TPV devices shown in FIG. 12A.

FIG. 13 illustrates the selectivity vs. average visible transmittance (AVT) for TPV devices including various materials in AR layers according to certain embodiments.

FIG. 14A illustrates examples of TPV devices each including a selective NIR absorbing material of a different respective thickness in a hole transport layer (HTL) according to certain embodiments.

FIG. 14B illustrates simulated performance of the examples of TPV devices shown in FIG. 14A.

FIG. 15A illustrates examples of TPV devices each including a transparent AR layer with an Ag electrode of a different respective thickness according to certain embodiments.

FIG. 15B illustrates simulated performance of the examples of TPV devices shown in FIG. 15A.

FIG. 16A illustrates examples of TPV devices each including SnNcCl₂ as a selective NIR absorbing material in an AR layer with an Ag electrode of a different respective thickness according to certain embodiments.

FIG. 16B illustrates simulated performance of the examples of TPV devices shown in FIG. 16A.

FIG. 17A illustrates examples of TPV devices each including SnNc as a selective NIR absorbing material in an AR layer with an Ag electrode of a different respective thickness according to certain embodiments.

FIG. 17B illustrates simulated performance of the examples of TPV devices shown in FIG. 17A.

FIG. 18A illustrates examples of TPV devices each including BBT as a selective NIR absorbing material in an AR layer with an Ag electrode of a different respective thickness according to certain embodiments.

FIG. 18B illustrates simulated performance of the examples of TPV devices shown in FIG. 18A.

FIG. 19 illustrates the selectivity vs. AVT for examples of TPV devices with different AR layers of fixed thickness and Ag electrodes of different thicknesses according to certain embodiments.

FIG. 20 illustrates techniques for improving the AVT and selectivity of TPV devices according to certain embodiments.

FIG. 21A illustrates examples of TPV devices each including HAT-CN as a transparent AR layer and an Ag electrode of a different respective thickness according to certain embodiments.

FIG. 21B illustrates simulated and measured performance of the examples of TPV devices shown in FIG. 21A.

FIG. 22A illustrates examples of TPV devices each including SnNcCl₂ as an NIR absorbing AR layer and an Ag electrode of a different respective thickness according to certain embodiments.

FIG. 22B illustrates simulated and measured performance of the examples of TPV devices shown in FIG. 22A.

FIG. 23A illustrates an example of a TPV device including NiDT as an NIR absorbing AR layer and an Ag electrode of a different respective thickness according to certain embodiments.

FIG. 23B illustrates simulated and measured performance of the example of TPV device shown in FIG. 23A.

FIG. 24A illustrates the AM1.5G energy flux of the solar spectrum and the photopic response of human eyes.

FIG. 24B illustrates transmission (T) and absorption (A) spectra of two TPV devices including either a transparent or NIR absorbing AR layer according to certain embodiments.

FIG. 25A illustrates visible solar irradiance spectra of two TPV devices each including an AR layer according to certain embodiments.

FIG. 25B illustrates transmitted solar irradiance of two TPV devices each including an antireflection layer according to certain embodiments.

FIG. 25C illustrates absorbed solar irradiance of two TPV devices each including an antireflection layer according to certain embodiments.

FIG. 26A illustrates an example of a low-e coating structure including a thin silver layer sandwiched between two ZnO layers.

FIG. 26B illustrates an example of a low-e coating structure in which a SnNcCl₂ layer replaces a first ZnO layer in the low-e coating structure shown in FIG. 26A according to certain embodiments.

FIG. 26C illustrates an example of a low-e coating structure in which a SnNcCl₂ layer replaces a second ZnO layer in the low-e coating structure shown in FIG. 26A according to certain embodiments.

FIG. 26D illustrates an example of a low-e coating structure in which SnNcCl₂ layers replace the ZnO layers in the low-e coating structure shown in FIG. 26A according to certain embodiments.

FIG. 26E illustrates simulated performance of examples of low-e coating structures shown in FIGS. 26A-26D according to certain embodiments.

FIG. 27 illustrates an example of a method for manufacturing a visibly transparent photovoltaic device according to certain embodiments.

The figures depict embodiments of the present disclosure for purposes of illustration only. For example, the transmission or absorption curves in some figures are for illustration purposes only and may not represent the transmission or absorption curve of a material used in an actual TPV device. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF SPECIFIC EMBODIMENTS

The present disclosure relates generally to window coatings. More particularly, and without limitation, disclosed herein are materials and devices that can be integrated into windows to reduce the radiation of heat (e.g., from the sun) through the window while maintaining a sufficient average visible transmittance (AVT) of the windows. The materials and devices may selectively absorb NIR light and transmit visible light and may be integrated into various layers of transparent or semitransparent photovoltaic devices used in windows or may be coated on regular windows. For example, the materials, alone or in combination with other layers in the photovoltaic devices, may improve the AVT, solar heat gain coefficient (SHGC), and light-to-solar gain ratio (or selectivity) between the AVT and the SHGC of the windows, in addition to generating electrical energy from the solar energy. Various inventive embodiments are described herein, including materials, combinations of materials, devices, systems, modules, methods, and the like.

According to certain embodiments, various selective NIR absorbing materials, such as SnNcCl₂, SnNc, and the like, may be incorporated into different layers of a transparent photovoltaic (TPV) device, such as the active layer, an antireflection (AR) layer for visible light, or a carrier transport layer, to achieve both a high AVT and a low SHGC. In some embodiments, the high AVT and low SHGC may be achieved using both the NIR absorbing materials and a metal layer, such as a silver layer. The metal layer may also function as a visibly transparent electrode in a TPV device.

Examples of materials that can be utilized as active/buffer (transport layers)/optical materials in various embodiments of the present invention include NIR absorbing materials and/or materials that are characterized by strong absorption peaks in the NIR region of the electromagnetic spectrum. NIR absorbing materials include phthalocyanines, porphyrins, naphthaloryanines, squaraines, boron-dipyrromethenes, naphthalenes, rylenes, perylenes, tetracyano quinoidal thiophene compounds, tetracyano indacene compounds, carbazole thiaporphyrin compounds, metal dithiolates, benzothiadiazole containing compounds, dicyanomethylene indanone containing compounds, combinations thereof, and the like. Example materials are described in U.S. Provisional Application Nos. 62/521,154, 62/521,158, 62/521,160, 62/521,211, 62/521,214, and 62/521,224, each filed on Jun. 16, 2017, which are hereby incorporated by reference in their entireties.

In one example, a visibly transparent photovoltaic device may include a visibly transparent substrate, a first visibly transparent electrode on the visibly transparent substrate, a second electrode, a visibly transparent photoactive layer between the first visibly transparent electrode and the second electrode, and a NIR absorbing AR layer (e.g., a passive non-photovoltaic layer). The visibly transparent photoactive layer may be configured to convert at least one of NIR or ultraviolet light into photocurrent. The NIR absorbing material layer may be characterized by a high absorption in the NIR band and a very low absorption in the visible band. As such, NIR light that may not be absorbed by the visibly transparent photoactive layer may be absorbed by the NIR absorbing AR layer, where only a small portion of the absorbed heat in the NIR light may be convected and/or radiated inward to the interior of a structure. Thus, the SHGC can be reduced, the AVT can be maintained, and the selectivity can be improved.

In general, the terms and phrases used herein have their art-recognized meaning, which can be found by reference to standard texts, journal references, and contexts known to those skilled in the art. The following definitions are provided to clarify their specific use in the context of the present disclosure.

As used herein, the term “visible light” may refer to light within a wavelength range from about 380 nm to about 750 nm, from about 400 nm to about 700 nm, or from about 450 nm to about 650 nm.

As used herein, the terms “visibly transparent” (or simply “transparent”) and “visibly semitransparent” (or simply “semitransparent”), and the like, may refer to a character of a material or device that exhibits an overall absorption, average absorption, or maximum absorption in the visible band within about 0%-70%, such as less than or about 70%, less than or about 65%, less than or about 60%, less than or about 55%, less than or about 50%, less than or about 45%, less than or about 40%, less than or about 35%, less than or about 30%, less than or about 25%, or less than or about 20%. Stated another way, visibly transparent materials may transmit 30%-100% of incident visible light, such as greater than or about 80% of incident visible light, greater than or about 75% of incident visible light, greater than or about 70% of incident visible light, greater than or about 65% of incident visible light, greater than or about 60% of incident visible light, greater than or about 55% of incident visible light, greater than or about 50% of incident visible light, greater than or about 45% of incident visible light, greater than or about 40% of incident visible light, greater than or about 35% of incident visible light, or greater than or about 30% of incident visible light. Some of the light not transmitted through the material or device may be scattered, reflected, or absorbed by the materials. Visibly transparent materials are generally considered at least partially see-through (i.e., not completely opaque) when viewed by a human. A visibly transparent photovoltaic device may be simply referred to as a TPV device.

As used herein, the term “maximum absorption strength” refers to the largest absorption value in a particular spectral region, such as the ultraviolet band (200 nm to 450 nm or 280 nm to 450 nm), the visible band (450 nm to 650 nm), or the near-infrared band (650 nm to 1400 nm). In some examples, a maximum absorption strength may correspond to an absorption strength of an absorption feature that is a local or absolute maximum, such as an absorption band or peak, and may be referred to as a peak absorption. In some examples, a maximum absorption strength in a particular band may not correspond to a local or absolute maximum but may instead correspond to the largest absorption value in the particular band. Such a configuration may occur, for example, when an absorption feature spans multiple bands (e.g., visible and near-infrared), and the absorption values from the absorption feature that occur within the visible band are smaller than those occurring within the near-infrared band, such as when the peak of the absorption feature is located within the ultraviolet band but a tail of the absorption feature extends to the visible band. In some embodiments, a visibly transparent photoactive compound described herein may have an absorption peak at a wavelength greater than about 650 nanometers (i.e., in the near-infrared) or at a wavelength less than about 450 nanometers (i.e., in the ultraviolet), and the visibly transparent photoactive material's absorption peak may be greater than the visibly transparent photoactive material's absorption at any wavelength between about 450 and 650 nanometers.

As used herein, the term “solar heat gain coefficient (SHGC)” may refer to the fraction of incident solar radiation admitted through a window, including both the portion directly transmitted and the portion absorbed and then re-radiated inward. SHGC may be described by a number between 0 and 1. In general, the lower a window's solar heat gain coefficient, the less solar heat it transmits. In some embodiments, a window's SHGC can be determined according to:

SHGC=Tₛₒₗ+Aₛₒₗ×N,

where Tₛ₀ₗ is the solar energy transmittance and Aₛₒₗ is the solar energy absorptance of the window for AM1.5D, and N is the fraction of the absorbed heat flowing inward through the window by both convection and radiation. Note that Tₛₒₗ and Aₛₒₗ are the fractions of incident solar radiation directly transmitted and absorbed by the window, respectively.

As used herein, the term “average visible transmittance (AVT)” may refer to the weighted average transmittance of visible light in the solar spectrum, where the weight may be determined based on the photopic response of human eyes and solar energy flux for each respective wavelength. In some embodiments, the AVT may be determined according to:

$$AVT = \frac{\int T ( λ ) P ( λ ) S ( λ ) d λ}{\int P ( λ ) S ( λ ) d λ} ,$$

where λ is the wavelength, T(λ) is the transmissivity of the device for light with a wavelength λ, P(λ) is the photopic response of human eye to light with a wavelength λ, and S(λ) is the solar energy flux (e.g., D65) at a wavelength λ for window applications, or 1 for some other applications.

As used herein, the term “selectivity” or “light-to-solar gain ratio (LSGR)” may refer to the ratio between the AVT and the SHGC of a window.

As used herein, the term “insulated glass unit (IGU)” may refer to an assembly including two or more glass pieces separated by thermal insulating spacers around the edges. The cavity between each pair of adjacent glass pieces may be a vacuum or may be filled with an inert gas, such as Argon, to reduce convective heat transfer through the unit. The unit may also be enclosed by framing around the edges. In some embodiments, the SHGC of an IGU may refer to the SHGC at the center of the glass pieces, while the effects of opaque elements, such as the framing, on SHGC may not be considered.

As used herein, the term “optical antireflection (OAR) layer” may refer to a layer that is deposited on a substrate or a top electrode (e.g., a metal film) and is used to reduce reflectivity at the substrate or the top electrode. It is often advantageous to use one or more visibly transparent (non-absorbing in the visible spectrum) materials as the OAR layer in order to maximize the AVT of a TPV device.

As used herein, the terms “hole transport layer (HTL)” and “electron transport layer (ETL)” may refer to layers that are highly conductive to either holes (e.g., HTL) or electrons (e.g., ETL), such that they do not significantly increase the electrical resistance of a device. The materials for the HTL or ETL may be chosen such that they may selectively conduct either holes or electrons while blocking the other type of charge carriers. In some embodiments, the ETL and/or HTL may also contribute to photocurrent.

Examples of abbreviations for some materials (e.g., some NIR or UV absorbing materials) that may be utilized in the present disclosure include:
TPBi: 2,2′,2″-(1,3,5-Benzinetriyl)-tris(1-phenyl-1-H-benzimidazole);
HAT-CN: Dipyrazino[2,3-f:2′,3′-h ]quinoxaline-2,3,6,7,10,11-hexacarbonitrile;
ZnO: Zinc oxide;
MoOs: Molybdenum trioxide;
C₆₀: Fullerene-C₆₀;
SnNc: Tin(II) 2,3-naphthalocyanine;
SnNcCl₂: Tin(IV) 2,3-naphthalocyanine dichloride;
BBT: 4,8-Bis[5-(N,N-diphenylamino)-2-thiophene]benzo[1,2-c:4,5-c(]bis[1,2,5]thiadiazole;
NiDT: Bis(dithiobenzil)nickel(II);
QQT: 2,2′-[(3,4-Dibutyl-2,5-thiophenediylidene)di-5,2-thiophenediylidene]bis[propanedinitrile]; and
UE-D-100: Proprietary NIR-absorbing donor material.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration. Any embodiment or design described herein as “example” is not necessarily to be construed as preferred or advantageous over other embodiments or designs.

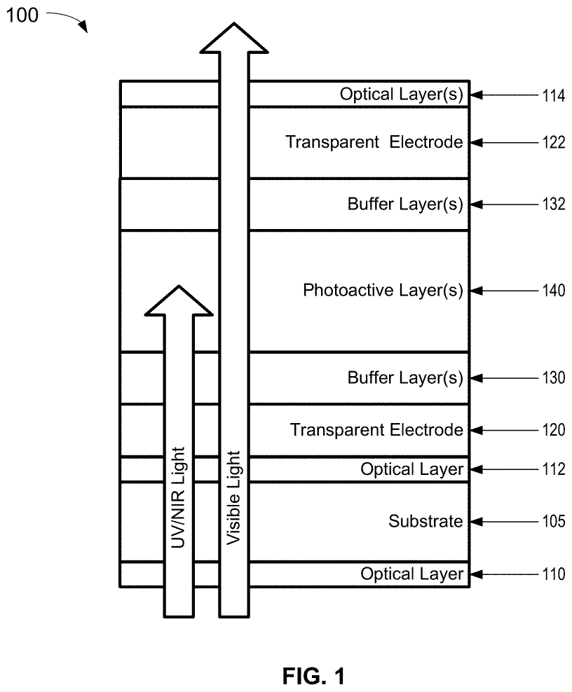

FIG. 1 is a simplified diagram illustrating an example of a visibly transparent photovoltaic (TPV) device 100 that is color neutral in the visible band according to certain embodiments. As illustrated in FIG. 1, visibly transparent photovoltaic device 100 may include a number of layers and elements. As described above, visibly transparent indicates that the photovoltaic device absorbs optical energy at wavelengths outside the visible wavelength band of, for example, about 450 nm to about 650 nm, while substantially transmitting light inside the visible wavelength band. As illustrated in the example, UV and/or NIR light may be strongly absorbed by the layers and elements of the photovoltaic device while visible light may be substantially transmitted through the device.

Visibly transparent photovoltaic (TPV) device 100 may include a substrate 105, which can be glass or other visibly transparent materials providing sufficient mechanical support to the other layers and structures illustrated. Example substrate materials include various glasses and rigid or flexible polymers. Multilayer substrates, such as laminates, may also be utilized.

Substrates may have any suitable thickness to provide the mechanical support needed for the other layers and structures, such as, for example, thicknesses from 0.5 mm to 20 mm. In some cases, the substrate may include an adhesive film to allow application of the visibly transparent photovoltaic device 100 to another structure, such as a window pane, display device, and the like. Substrate 105 may support optical layers 110 and 112. These optical layers can provide a variety of optical properties, including antireflection (AR) properties, wavelength selective reflection or distributed Bragg reflection properties, index matching properties, encapsulation, or the like. Optical layers 110 and 112 may advantageously be visibly transparent. An additional optical layer 114 can be utilized, for example, as an AR coating, an index matching layer, a passive visible light, infrared light, or ultraviolet light absorbing layer, and the like. Optionally, optical layers 110-114 may be transparent to visible light, ultraviolet light, and/or near-infrared light or transparent to at least a subset of wavelengths in visible, ultraviolet, and/or near-infrared bands. Depending on the configuration, additional optical layer 114 may also be a passive visible light absorbing layer.

Although the devices overall may exhibit visible transparency, such as a transparency in the 450-650 nm range greater than 30%, greater than 40%, greater than 50%, greater than 60%, greater than 70%, or up to or approaching 100%, certain materials taken individually may exhibit absorption in at least some portions of the visible spectrum. Optionally, each individual material or layer in a visibly transparent photovoltaic device may have a high transparency in the visible range, such as greater than 30% (e.g., between 30% and 100%). Transmission or absorption may be expressed as a percentage and may be dependent on the material's absorbance properties, a thickness or path length through an absorbing material, and a concentration of the absorbing material, such that a material with an absorbance in the visible band may exhibit a low absorption or high transmission if the path length through the absorbing material is short and/or the absorbing material is present in low concentration.

As described herein and below, photoactive materials in various photoactive layers may advantageously exhibit minimal absorption in the visible band (e.g., less than 20%, less than 30%, less than 40%, less than 50%, less than 60%, or less than 70%), and high absorption in the near-infrared and/or ultraviolet bands (e.g., an absorption peak of greater than 50%, greater than 60%, greater than 70%, or greater than 80%). For some applications, the absorption in the visible band may be as large as 70%. Various configurations of other materials, such as the substrate, optical layers, and buffer layers, may allow these materials to provide overall visible transparency, even though the materials may exhibit some amount of visible absorption. For example, a thin film of a metal, such as Ag or Cu, may be included in a transparent electrode. The metal may absorb visible light; however, when provided in a thin film configuration, the overall transparency of the film may be high. Similarly, materials included in an optical or buffer layer may exhibit absorption in the visible range, but may be provided at a concentration or thickness such that the overall amount of visible light absorption is low, providing visible transparency.

Visibly transparent photovoltaic device 100 may include a set of transparent electrodes 120 and 122 with a photoactive layer 140 positioned between electrodes 120 and 122. Electrodes 120 and 122, which can be fabricated using indium tin oxide (ITO), fluorine-doped tin oxide (FTO), thin metal films, or other suitable visibly transparent materials, provide electrical connection to one or more of the various layers illustrated. For example, thin films of copper, silver, or other metals may be suitable for use as a visibly transparent electrode, even though these metals may absorb light in the visible band. When provided as a thin film, such as a film having a thickness about 1 nm to about 200 nm (e.g., about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 105 nm, about 110 nm, about 115 nm, about 120 nm, about 125 nm, about 130 nm, about 135 nm, about 140 nm, about 145 nm, about 150 nm, about 155 nm, about 160 nm, about 165 nm, about 170 nm, about 175 nm, about 180 nm, about 185 nm, about 190 nm, or about 195 nm), an overall transmittance of the thin film in the visible band may remain high, such as greater than 30%, greater than 40%, greater than 50%, greater than 60%, greater than 70%, greater than 80%, or greater than 90%. Advantageously, thin metal films, when used as transparent electrodes, may exhibit lower absorption in the ultraviolet band than some semiconducting materials that may be useful as a transparent electrode, such as ITO, as some semiconducting transparent conducting oxides may have a band gap in the ultraviolet band and thus may be highly absorbing or opaque to ultraviolet light. In some cases, however, an ultraviolet absorbing transparent electrode may be used, such as to screen at least a portion of the ultraviolet light from underlying components, because ultraviolet light may degrade certain materials.

A variety of deposition techniques may be used to generate a transparent electrode, including vacuum deposition techniques, such as atomic layer deposition, chemical vapor deposition, physical vapor deposition, thermal evaporation, sputter deposition, epitaxy, and the like. Solution based deposition techniques, such as spin-coating, may also be used in some cases. In addition, transparent electrodes may be patterned using techniques for microfabrication, including lithography, lift off, etching, and the like.

Buffer layers 130 and 132 and photoactive layer 140 are utilized to achieve the electrical and optical properties of the photovoltaic device. These layers can be layers of a single material or can include multiple sub-layers as appropriate for the particular application. Thus, the term “layer” is not intended to denote a single layer of a single material, but can include multiple sub-layers of the same or different materials. In some embodiments, buffer layer 130, photoactive layer(s) 140, and buffer layer 132 are repeated in a stacked configuration to provide tandem device configurations, such as multi junction cells. In some embodiments, photoactive layer(s) 140 may include electron donor materials and electron acceptor materials, also referred to as donors and acceptors. These donors and acceptors are visibly transparent, but may absorb outside the visible wavelength band to generate photocurrent.

Buffer layers 130 and 132 may function as electron transport layers, electron blocking layers, hole transport layers, hole blocking layers, exciton blocking layers, optical spacers, physical buffer layers, charge recombination layers, charge generation layers, or the like. Buffer layers 130 and 132 may have any suitable thickness to provide the buffer effect desired and may optionally be present or absent. Buffer layers 130 and 132, when present, may have thicknesses from about 1 nm to about 100 nm. Additionally, buffer layers 130 and 132 may have absorptivity complimentary to phtotoactive layers in some embodiments. Various materials may be used as buffer layers, including fullerene materials, carbon nanotube materials, graphene materials, metal oxides, such as molybdenum oxide, titanium oxide, zinc oxide, and the like., polymers, such as poly(3,4-ethylenedioxythiophene), polystyrene sulfonic acid, polyaniline, and the like., copolymers, polymer mixtures, and small molecules, such as bathocuproine. Buffer layers may be formed using a deposition process (e.g., thermal evaporation) or a solution processing method (e.g., spin coating), and may include one or more layers.

Various compounds, such as tetracyano quinoidal thiophene compounds, tetracyano indacene compounds, carbazole thiaporphyrin compounds, and/or dithiophene squarine compounds, may be used as one or more of the buffer layers, optical layers, and/or the photoactive layers. These compounds can include suitably functionalized versions for modification of the electrical and/or optical properties of the core structure. As an example, the disclosed compounds can include functional groups that decrease the absorption in the visible wavelength band from about 450 nm to about 650 nm and increase the absorption in the NIR band at wavelengths greater than about 650 nm.

Examples of materials that can be utilized as active/buffer (transport layers)/optical materials in various embodiments of the present invention include near-IR absorbing materials, UV absorbing materials, and/or materials that are characterized by strong absorption peaks in the near-IR or UV regions of the electromagnetic spectrum. Examples of near-IR absorbing materials may include phthalocyanines, porphyrins, naphthalocyanines, squaraines, boron-dipyrromethenes, naphthalenes, rylenes, perylenes, para-phenylenes, tetracyano quinoidal thiophene compounds, tetracyano indacene compounds, carbazole thiaporphyrin compounds, metal dithiolates, benzothiadiazole containing compounds, dicyanomethylene indanone containing compounds, combinations thereof, and the like. Examples of UV absorbing materials include fullerenes, rylenes, perylenes, benzimidazoles, hexacarbonitriles, triarylamines, bistriarylamines, phenanthrolines, combinations thereof, and the like.

It is noted that, in various embodiments, visibly transparent photovoltaic device 100 may include transparent electrode 120, photoactive layer 140, and transparent electrode 122, while any one or more of substrate 105, optical layers 110, 112, and 114, and buffer layers 130 and 132 may be optionally included or excluded.

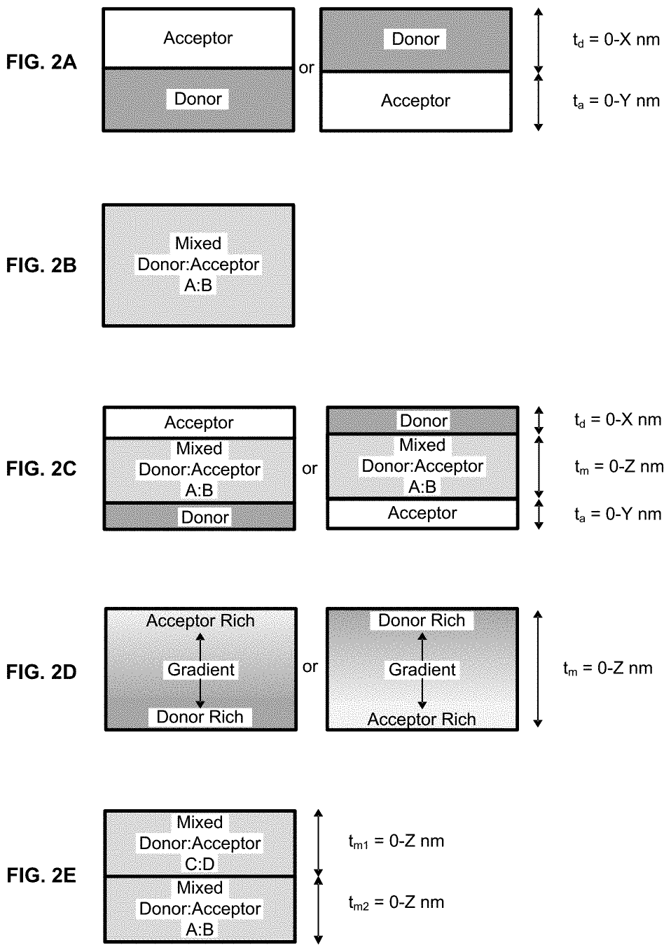

FIGS. 2A-2E illustrate various example junction configurations for photoactive layer 140. Photoactive layer 140 may optionally correspond to planar donor/acceptor configurations (as shown in FIG. 2A), mixed donor/acceptor (bulk heterojunction) configurations (as shown in FIG. 2B), planar and mixed donor/acceptor configurations (as shown in FIG. 2C), gradient donor/acceptor configurations (as shown in FIG. 2D), or stacked heterojunction configurations (as shown in FIG. 2E).

Various materials may optionally be used as the photoactive layers 140, such as materials that absorb in the ultraviolet band or the near-infrared band but that only absorb minimally, if at all, in the visible band. In this way, the photoactive material may be used to generate electron-hole pairs for powering an external circuit by way of ultraviolet and/or near-infrared absorption, leaving the visible light relatively unperturbed to provide visible transparency. As illustrated, photoactive layer 140 may comprise a planar heterojunction including separate donor and acceptor layers. Photoactive layer 140 may alternatively comprise a planar-mixed heterojunction structure including separate acceptor and donor layers and a mixed donor-acceptor layer. Photoactive layer 140 may alternatively comprise a mixed heterojunction structure including a fully mixed acceptor-donor layer or those including a mixed donor-acceptor layer with various relative concentration gradients.

Photoactive layers may have any suitable thickness and may have any suitable concentration or composition of photoactive materials to provide a desired level of transparency and ultraviolet/near-infrared absorption characteristics. Example thicknesses of a photoactive layer may range from about 1 nm to about 1μm, about 1 nm to about 300 nm, or about 1 nm to about 100 nm. In some cases, photoactive layers may be made up of individual sub-layers or mixtures of layers to provide suitable photovoltaic power generation characteristics, as illustrated in FIGS. 2A-2E. The various configurations depicted in FIGS. 2A-2E may be used and dependent on the particular donor and acceptor materials used in order to provide advantageous photovoltaic power generation. For example, some donor and acceptor combinations may benefit from particular configurations, while other donor and acceptor combinations may benefit from other particular configurations. Donor materials and acceptor materials may be provided in any ratio or concentration to provide suitable photovoltaic power generation characteristics. For mixed layers, the relative concentration of donors to acceptors is optionally between about 20 to 1 and about 1 to 20. Optionally, the relative concentration of donors to acceptors is optionally between about 5 to 1 and about 1 to 5. Optionally, donors and acceptors are present in a 1 to 1 ratio.

Various visibly transparent photoactive compounds are useful as an electron donor photoactive material and, in some embodiments, may be paired with suitable electron acceptor photoactive materials in order to provide a useful photoactive layer in the photovoltaic device. Various visibly transparent photoactive compounds are useful as an electron acceptor photoactive material and may be paired with suitable electron donor photoactive materials in order to provide a useful photoactive layer in the photovoltaic device. Example donor and acceptor materials are described in U.S. Provisional Application Nos. 62/521,154, 62/521,158, 62/521,160, 62/521,211, 62/521,214, and 62/521,224, each filed on Jun. 16, 2017, which are hereby incorporated by reference in their entireties.

In some embodiments, the chemical structure of various photoactive compounds can be functionalized with one or more directing groups, such as electron donating groups, electron withdrawing groups, or substitutions about or to a core metal atom, in order to provide desirable electrical characteristics to the material. For example, in some embodiments, the photoactive compounds are functionalized with amine groups, phenol groups, alkyl groups, phenyl groups, or other electron donating groups to improve the ability of the material to function as an electron donor in a photovoltaic device. As another example, in some embodiments, the photoactive compounds are functionalized with cyano groups, halogens, sulfonyl groups, or other electron withdrawing groups to improve the ability of the material to function as an electron acceptor in a photovoltaic device.

In embodiments, the photoactive compounds are functionalized to provide desirable optical characteristics. For example, in some embodiments, the photoactive compounds may be functionalized with an extended conjugation to redshift the absorption profile of the material. It will be appreciated that conjugation may refer to a delocalization of pi electrons in a molecule and may be characterized by alternating single and multiple bonds in a molecular structure. For example, functionalizations that extend the electron conjugation may include fusing one or more aromatic groups to the molecular structure of the material. Other functionalizations that may provide extended conjugation include alkene functionalization, such as by a vinyl group, aromatic or heteroaromatic functionalization, carbonyl functionalization, such as by an acyl group, sulfonyl functionalization, nitro functionalization, cyano functionalization, etc. It will be appreciated that various molecular functionalizations may impact both the optical and the electrical properties of the photoactive compounds.

It will be appreciated that device function may be impacted by the morphology of the active layers in the solid state. Separation of electron donors and acceptors into discrete domains, with dimensions on the scale of the exciton diffusion length and large interfacial areas, can be advantageous for achieving high device efficiency. Advantageously, the molecular framework of the photoactive materials can be tailored to control the morphology of the materials. For example, the introduction of functional groups as described herein can have large impacts to the morphology of the material in the solid state, regardless of whether such modifications impact the energetics or electronic properties of the material. Such morphological variations can be observed in pure materials and when a particular material is blended with a corresponding donor or acceptor. Useful functionalities to control morphology include, but are not limited to, addition of alkyl chains, conjugated linkers, fluorinated alkanes, bulky groups (e.g., tert-butyl, phenyl, naphthyl or cyclohexyl), as well as more complex coupling procedures designed to force parts of the structure out of the plane of the molecule to inhibit excessive crystallization.

In embodiments, other molecular structural characteristics may provide desirable electrical and optical properties in the photoactive compounds. For example, in some embodiments, the photoactive compounds may exhibit portions of the molecule that may be characterized as electron donating while other portions of the molecule may be characterized as electron accepting. Without wishing to be bound by any theory, molecules including alternating electron donating and electron accepting portions may result in redshifting the absorption characteristics of the molecule as compared to similar molecules lacking alternating electron donating and electron accepting portions. For example, alternating electron donating and electron accepting portions may decrease or otherwise result in a lower energy gap between a highest occupied molecular orbital and a lowest unoccupied molecular orbital. Organic donor and/or acceptor groups may be useful as R-group substituents, such as on any aryl, aromatic, heteroaryl, heteroaromatic, alkyl, or alkenyl group, in the visibly transparent photoactive compounds.

When the donor/acceptor materials are incorporated as a photoactive layer in a transparent photovoltaic device as either an electron donor or electron acceptor, the layer thicknesses can be controlled to vary device output, absorbance, or transmittance. For example, increasing the donor or acceptor layer thickness can increase the light absorption in that layer. In some cases, increasing a concentration of donor/acceptor materials in a donor or acceptor layer may similarly increase the light absorption in that layer. However, in some embodiments, a concentration of donor/acceptor materials may not be adjustable, such as when active material layers comprise pure or substantially pure layers of donor/acceptor materials or pure or substantially pure mixtures of donor/acceptor materials. Optionally, donor/acceptor materials may be provided in a solvent or suspended in a carrier, such as a buffer layer material, in which case the concentration of donor/acceptor materials may be adjusted. In some embodiments, the donor layer concentration is selected where the current produced is maximized. In some embodiments, the acceptor layer concentration is selected where the current produced is maximized.

However, the charge collection efficiency can decrease with increasing donor or acceptor thickness due to the increased “travel distance” for the charge carriers. Therefore, there may be a trade-off between increased absorption and decreasing charge collection efficiency with increasing layer thickness. It can thus be advantageous to select materials that have a high absorption coefficient and/or concentration to allow for increased light absorption per thickness. In some embodiments, the donor layer thickness is selected where the current produced is maximized. In some embodiments, the acceptor layer thickness is selected where the current produced is maximized.

In addition to the individual photoactive layer thicknesses, the thickness and composition of the other layers in the transparent photovoltaic device can also be selected to enhance absorption within the photoactive layers. The other layers (buffer layers, electrodes, etc.), are typically selected based on their optical properties (index of refraction and extinction coefficient) in the context of the thin film device stack and resulting optical cavity. For example, a near-infrared absorbing photoactive layer can be positioned in the peak of the optical field for the near-infrared wavelengths where it absorbs to maximize absorption and resulting current produced by the device. This can be accomplished by spacing the photoactive layer at an appropriate distance from the electrode using a second photoactive layer and/or optical layers as spacer. A similar scheme can be used for ultraviolet absorbing photoactive layers. In many cases, the peaks of the longer wavelength optical fields will be positioned further from the more reflective of the two transparent electrodes compared to the peaks of the shorter wavelength optical fields. Thus, when using separate donor and acceptor photoactive layers, the donor and acceptor can be selected to position the more red-absorbing (longer wavelength) material further from the more reflective electrode and the more blue absorbing (shorter wavelength) closer to the more reflective electrode.

In some embodiments, optical layers may be included to increase the intensity of the optical field at wavelengths where the donor absorbs in the donor layer to increase light absorption and hence, increase the current produced by the donor layer. In some embodiments, optical layers may be included to increase the intensity of the optical field at wavelengths where the acceptor absorbs in the acceptor layer to increase light absorption and hence, increase the current produced by the acceptor layer. In some embodiments, optical layers may be used to improve the transparency of the stack by either decreasing visible absorption or visible reflection. Further, the electrode material and thickness may be selected to enhance absorption outside the visible range within the photoactive layers, while preferentially transmitting light within the visible range.

Optionally, enhancing spectral coverage of a visibly transparent photovoltaic device is achieved by the use of a multi-cell series stack of visibly transparent photovoltaic devices, referred to as tandem cells, which may be included as multiple stacked instances of buffer layer 130, photoactive layer 140, and buffer layer 132, as described with reference to FIG. 1. This architecture includes more than one photoactive layer, which are typically separated by a combination of buffer layer(s) and/or thin metal layers, for example. In this architecture, the currents generated in each subcell flow in series to the opposing electrodes and therefore, the net current in the cell is limited by the smallest current generated by a particular subcell, for example. The open circuit voltage (Voc) is equal to the sum of the Voc values of the subcells. By combining sub-cells fabricated with different donor-acceptors pairs which absorb in different regions of the solar spectrum, a significant improvement in efficiency relative to a single junction cell can be achieved.

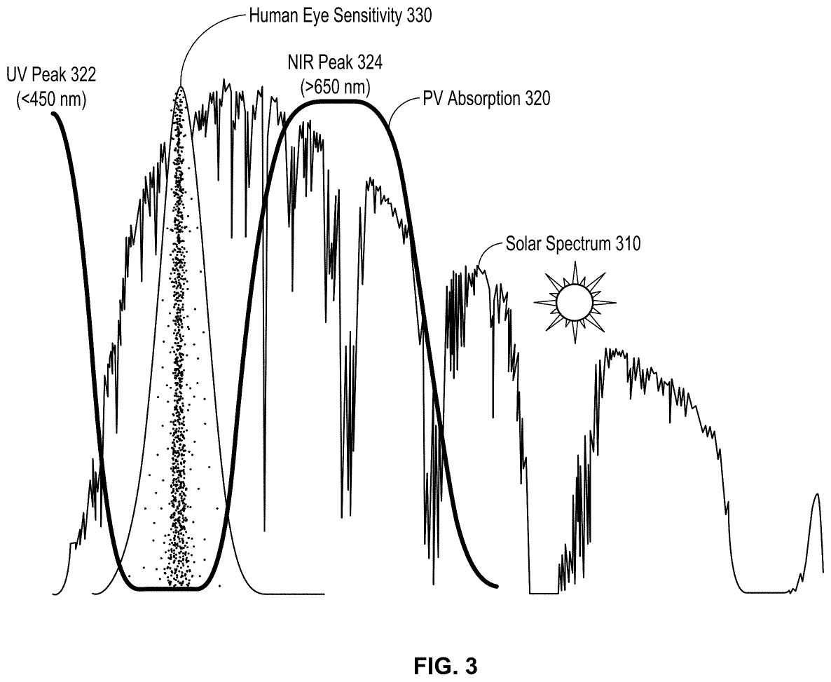

FIG. 3 is simplified plot 300 illustrating the solar spectrum 310, human eye sensitivity 330, and the absorption spectrum 320 of an example of a transparent photovoltaic device as a function of light wavelength. As illustrated in FIG. 3, embodiments in the present disclosure may utilize photovoltaic structures that have low and uniform absorption in the visible wavelength band between about 450 nm and about 650 nm, but strongly absorb in the UV and NIR bands, i.e., outside the visible wavelength band, enabling visibly transparent photovoltaic operation. The ultraviolet band may be described, in embodiments, as wavelengths of light between about 200 nm and about 450 nm. It will be appreciated that useful solar radiation at ground level may have limited amounts of ultraviolet light with wavelengths less than about 280 nm, and thus, in some embodiments, the ultraviolet band or ultraviolet region may be described as wavelengths of light between about 280 nm and 450 nm. The near-infrared band may be described, in embodiments, as wavelengths of light of between about 650 nm and about 1400 nm.

Various compositions and compounds may exhibit absorption including a UV peak 322 and/or a NIR peak 324, and a maximum absorption strength in the visible band smaller than that in the NIR region or UV region. Some of these compositions and compounds may be photoactive and may be used in the visibly transparent photovoltaic devices decribed above and below to convert solar light outside of the visible band into electricity. For example, the photoactive compounds may optionally exhibit a peak absorption in the near-infrared band. Optionally, the photoactive compounds may have a peak absorption in the ultraviolet band. To achieve desired optical properties, visibly transparent photoactive compounds may have a molecular electronic structure for absorbing photons of ultraviolet or near-infrared light, which may result in the promotion of an electron from a lower molecular orbital level to a higher molecular orbital level, where an energy difference between the lower molecular orbital level to the higher molecular orbital level may match the energy of the absorbed photon. Compounds exhibiting extended aromaticity or extended conjugation are beneficial, as compounds with extended aromaticity or extended conjugation may exhibit electronic absorption with energies matching that of ultraviolet and/or near-infrared photons. In some cases, however, extended aromaticity or extended conjugation may result in absorption in the visible band (i.e., between about 450 nm and about 650 nm) as well. In addition to conjugation and aromaticity, absorption features may be modulated by inclusion of heteroatoms in the organic structure of the visibly transparent photoactive compounds, such as nitrogen or sulfur atoms. Additionally or alternatively, absorption features may be modulated by the presence and positions of metal atoms and organo metallic bonding. Additionally or alternatively, absorption features may be modulated by the presence and positions of electron donating or electron withdrawing groups, such as halogen atoms, alkyl groups, alkoxy groups, and the like, bonded to a core or sub-structure of the visibly transparent photoactive compounds. Further, absorption features may optionally be modulated by the presence of electron donor groups or electron acceptor group within a photoactive compound.

Examples of photoactive compounds that may be used for a photoactive layer in a visibly transparent photovoltaic device include those incorporating quinoidal structures, tetracyano quinoidal thiophene structures, tetracyano indacene structures, carbazole thiaporphyrin structures, and dithiophene squarine structures.

The other layers used in the visibly transparent photovoltaic devices may exhibit suitable compositions and properties for operation of the transparent photovoltaic device. For example, various visibly transparent substrates may be used, such as those including transparent glasses, transparent polymers, and the like. In some embodiments, the visibly transparent substrate may be transparent to near-infrared light (e.g., light with a wavelength greater than 650 nm) and/or ultraviolet light (e.g., light with a wavelength less than 450 nm). In this way, the visibly transparent substrate may not absorb near-infrared and/or ultraviolet light that would be suitable for photovoltaic energy generation by the visibly transparent photovoltaic devices. In some embodiments, however, the visibly transparent substrate may absorb infrared and/or ultraviolet light, which may be useful, for example, for configurations where the visibly transparent substrate serves to block excess infrared or visible radiation incident radiation after passing through the photoactive layer(s) to prevent or reduce overall ultraviolet and/or infrared transmission. Useful visibly transparent substrates include, but are not limited to, those having thicknesses of about 50 nm to about 30 mm.

Examples of visibly transparent electrodes include indium tin oxide (ITO) or thin transparent films of conductive metals, such as copper, gold, silver, aluminum, and the like, or associated metal alloys. In cases where the visibly transparent electrodes include conductive metals, the thicknesses of the visibly transparent electrodes may be such that even though the conductive metals may be opaque in the bulk, when used as a thin film, the conductive metals may still allow for the transmission of visible light. Useful visibly transparent electrodes include, but are not limited to, those having thicknesses of about 1 nm to about 500 nm.

As described above, other layers may also be present in the visibly transparent photovoltaic devices described herein. For example, a visibly transparent photovoltaic device may optionally include one or more buffer layers, such as a first buffer layer disposed between the first visibly transparent electrode and the first visibly transparent photoactive layer and/or a second buffer layer disposed between the first (or a second) visibly transparent photoactive layer and the second visibly transparent electrode. The buffer layers may serve a variety of purposes and include various compositions. For example, in some cases, a buffer layer may include a photoactive material or compound described herein. Optionally, the buffer layers may have thicknesses of about 1 nm to about 500 nm.

The TPV devices described above may be used in, for example, IGUs of windows. The IGUs may have different configurations. For the purposes of explanation, specific examples are described in order to provide a thorough understanding of certain inventive embodiments. However, the examples are not intended to be restrictive. For example, in some examples, the IGUs are shown as double glazing units, but a skilled person would readily understand that the techniques disclosed herein can be applied to glazing units with triple, quadruple, or even higher numbers of glass panes or lites.

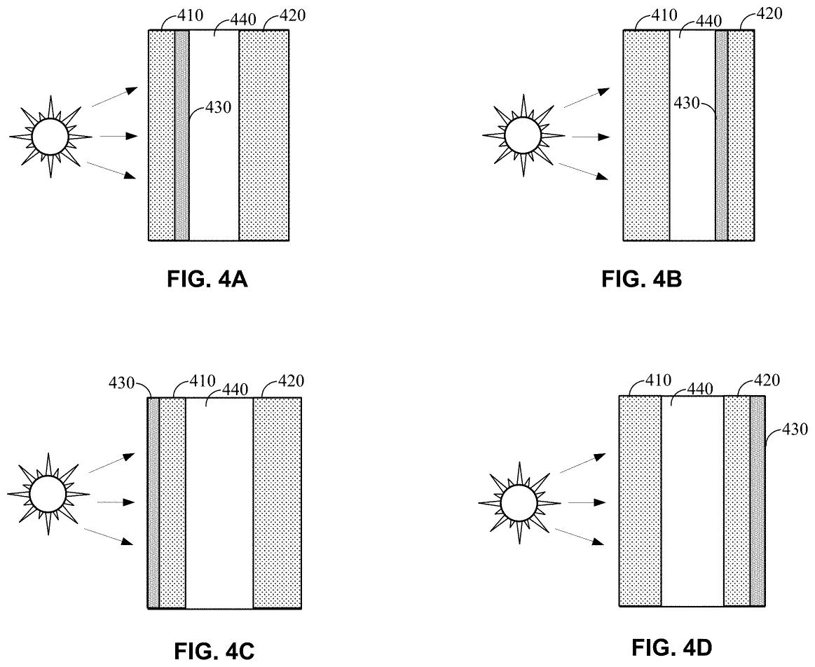

FIGS. 4A-4D illustrate various configurations of a PV layer 430 in a double-pane IGU according to certain embodiments. The double-pane IGU may include a first glass pane 410 and a second glass pane 420 that form a gap 440 in between. First glass pane 410 may be the glass pane that is closer to the external environment, and second glass pane 420 may be closer to the interior of a building after installation on the building. Gap 440 may be filled with, for example, an inert gas, such as Ar, to reduce convective heat transfer through the IGU. Solar light may first enter the IGU through first glass pane 410. In one example, the IGU may have an area of 1 m×1 m and a thickness of about 20 mm. For example, first glass pane 410 may have a thickness about 1 mm (e.g., about 0.7 mm), second glass pane 420 may have a thickness greater than 1 mm (e.g., >about 5 mm), and gap 440 may have a length about 15 mm.

As described above, PV layer 430 may include one or more active layers, two transparent electrode layers, and other layers as described above and below in the present disclosure. For example, in some implementations, PV layer 430 may include one or more reflecting layers, such as a metal layer, and/or one or more absorption layer, such as a selective NIR absorbing layer. PV layer 430 may have a thickness less than about a few microns, or less than about a few hundred nanometers. As shown in FIGS. 4A-4D, PV layer 430 can be deposited onto any surface of any IGU glass pane 410 or 420 and can be incorporated into the IGU stack on the external surface of the IGU or the internal surface of the IGU (e.g., the surfaces forming gap 440). For example, in FIG. 4A, PV layer 430 may be deposited on a surface of first glass pane 410 facing gap 440. In FIG. 4B, PV layer 430 may be deposited on a surface of second glass pane 420 facing gap 440. In FIG. 4C, PV layer 430 may be deposited on a surface of first glass pane 410 facing the external environment. In FIG. 4D, PV layer 430 may be deposited on a surface of second glass pane 420 facing the interior of the building.

In various embodiments of IGUs, the PV layer can be placed at any location within an IGU having more than two panes of glass (e.g., triple glazing units). For example, the PV layer can be placed at any location on the front or back glass panes as well as on either side of any of internal glass piece for a triple glazing unit. The PV layer may also be placed on either side of any of the glass panes of a multi-glazing units with n glass panes. In the examples described below, the IGU structure shown in FIG. 4A may be used for the description, simulations, and measurements, for illustration purposes only. Techniques described herein can be used in other IGU structures, where the IGUs may or may not include photoactive layers.

IGUs, such as the IGUs shown in FIGS. 4A-4D, may gain or lose heat through direct conduction through the glass, glazing, and frame, as well as the radiation of heat through the window. A technique to decrease SHGC is using thin layers of high reflectivity metals that reflect most of the NIR light. This technique may result in a high selectivity but may also simultaneously reduce the AVT.

According to certain embodiments, in order to reduce the radiation of heat (e.g., NIR light from the sun) through the window while maintaining sufficiently high AVT of the windows (e.g., >0.45), selective NIR absorbing materials may be integrated into various layers of the TPV devices used in the IGUs or may be coated on regular windows. The NIR absorbing materials may selectively absorb NIR light from a heat source (e.g., the sun) to reduce the heat transmitted through the IGUs via convection or radiation while still transmitting visible light. In some embodiments, a high AVT and low SHGC may be achieved using both the NIR absorbing materials and a metal layer, such as a silver layer.

As described above, the SHGC of an IGU may be determined according to SHGC=Tₛₒₗ+Aₛₒₗ×N. The fraction N of absorbed heat flowing inward through the IGU due to convection and radiation may be small, such as less than about 20%, less than about 10%, or less than about 5%. Therefore, increasing solar absorptance Aₛₒₗ of the IGU by m percent may reduce the solar transmittance Tₛₒₗ of the window by m percent, while only slightly increasing the inward flowing of the absorbed heat. Thus, the window's SHGC may be reduced by close to, for example, 0.8×m percent (e.g., when N=20%), 0.95×m percent (e.g., when N=5%), or more. Therefore, the IGUs including selective NIR absorbing materials may have both a high heat isolation (or a lower SHGC) and a high selectivity.

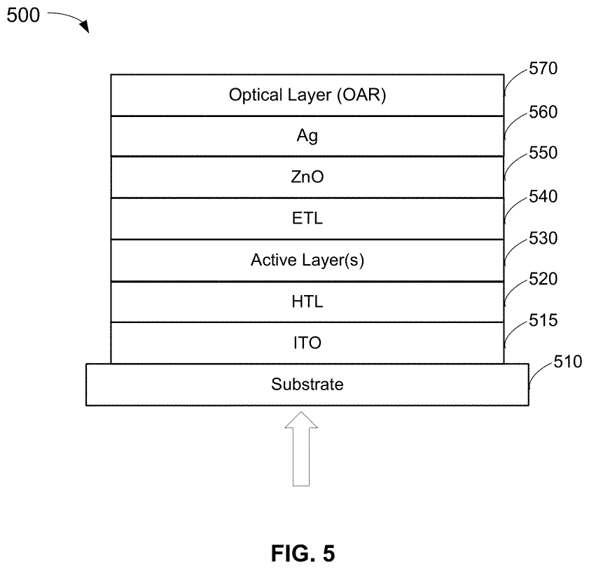

FIG. 5 illustrates an example of a visibly transparent photovoltaic device 500 including multiple layers that can include a near-infrared absorbing material according to certain embodiments. Visibly transparent photovoltaic device 500 may include a substrate 510, two transparent electrodes, a stack between the two electrodes, and an optical layer 570 on one of the transparent electrodes. Substrate 510 may include, for example, glass, polymers, or other visibly transparent materials, and may have any suitable thickness. Optical layer 570 can provide a variety of optical properties, including optical antireflection (OAR) properties at visible wavelengths, wavelength selective reflection properties, index matching properties, or the like. For example, optical layer 570 may be used to reduce the reflection of visible light at the interface between visibly transparent photovoltaic device 500 and air. In some embodiments, visibly transparent photovoltaic device 500 may also include one or more optical layers (such as optical layers 110 and 112) on one or both sides of substrate 510.

The two transparent electrodes may include an anode and a cathode, which may include, for example, thin layers of metals and/or conductive oxides, such as indium tin oxide (ITO), fluorine-doped tin oxide (FTO), or the like. In the example shown in FIG. 5, the anode may include, for example, an ITO layer 515, and the cathode may include, for example, a silver layer 560 on a ZnO layer 550.

The stack between the two transparent electrodes may include an HTL layer 520, one or more active layer 530, and an ETL layer 540. HTL layer 520 may be highly conductive for holes, and may include, for example, conductive metal oxides such as MoO₃, WO₃, NiOx, or V₂O₅, ITO, polymers such as PEDOT:PSS, or the like. ETL layer 540 may be highly conductive for electrons, and may include, for example, a thin layer of a metal oxide, such as zinc oxide (ZnO), indium oxide (IN₂O₃), tin oxide (SnO₂), titanium oxide (TiO₂), barium stannate (BaSnO₃), AZO, FTO, Al:MoO3, PEIE, or the like. In some embodiments, ZnO layer 550 may be part of ETL layer 540. One or more active layers 530 may include photoactive layers that include one or more donor materials and one or more acceptor materials, or one or more mixed donor/acceptor materials as described above with respect to, for example, photoactive layer 140 of FIG. 1 and the examples of photoactive layers shown in FIG. 2A-2E.

Selective NIR absorbing materials may be incorporated into visibly transparent photovoltaic device 500 as an additional layer or may be incorporated into one or more layers of, for example, HTL layer 520, ETL layer 540, optical layer 570, and active layers 530. HTL layer 520, ETL layer 540, optical layer 570, and active layers 530 may each include one or more materials in a layered or blended structure as described above with respect to FIGS. 1-2E. Thus, the selective NIR absorbing material may be a separate layer in one of HTL layer 520, ETL layer 540, optical layer 570, and active layers 530, or may be blended with other materials in HTL layer 520, ETL layer 540, optical layer 570, and active layers 530. Examples of the selective NIR absorbing materials may include, but are not limited to, SnNcCl₂, SnNc, BBT, NiDT, QQT, and the like.

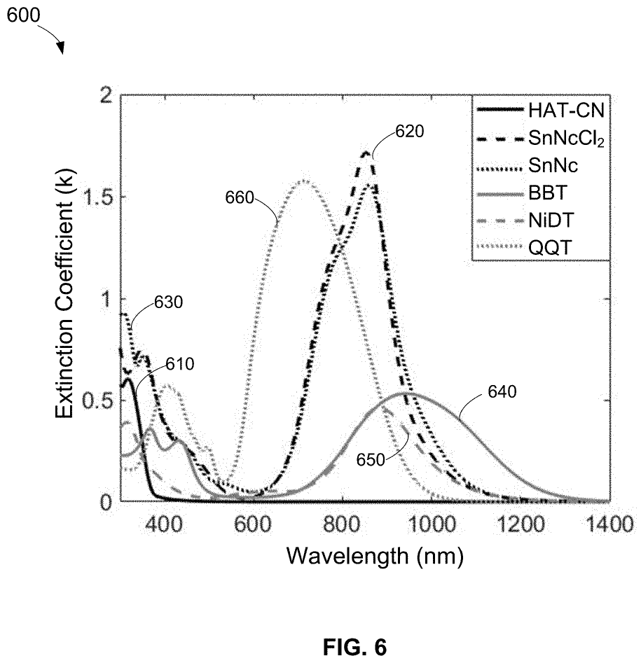

FIG. 6 is a chart 600 illustrating extinction coefficients of examples of materials that may be used in coating layers in IGUs according to certain embodiments. Optical properties of isotropic materials may generally be described using the complex refractive index ñ=n−ik, where n may be the ordinary refractive index, and k may be the extinction coefficient. Both n and k may be positive real numbers, which may be functions of the wavelength of the light propagating in the materials. The examples of materials shown in FIG. 6 may include compounds such as HAT-CN, SnNcCl₂, SnNc, BBT, NiDT, and QQT.

The extinction coefficient of HAT-CN may be illustrated by a curve 610 in FIG. 6, which may have a peak at a wavelength below about 400 nm and may be close to zero at wavelengths greater than about 400 nm. Thus, HAT-CN may be a visibly-transparent, UV absorbing material. In addition, HAT-CN may be transparent for near-infrared light. The extinction coefficients of SnNcCl₂, SnNc, BBT, NiDT, and QQT may be illustrated by a curve 620, a curve 630, a curve 640, a curve 650, and a curve 660, respectively, which may have peaks at wavelengths longer than about 600 nm. Thus, SnNcCl₂, SnNc, BBT, NiDT, and QQT may be considered NIR absorbing materials. Among these materials, QQT may have high extinction coefficients in portions of the visible band as shown by curve 660, and thus may reduce AVT if used in window coatings. BBT and NiDT may have lower extinction coefficients in the NIR band as shown by curves 640 and 650, and thus may have lower NIR absorptance. SnNcCl₂ and SnNc may have high extinction coefficients in the NIR band and very low extinction coefficients in the visible band as indicated by curves 620 and 630, and thus may strongly absorb NIR light and transmit visible light.

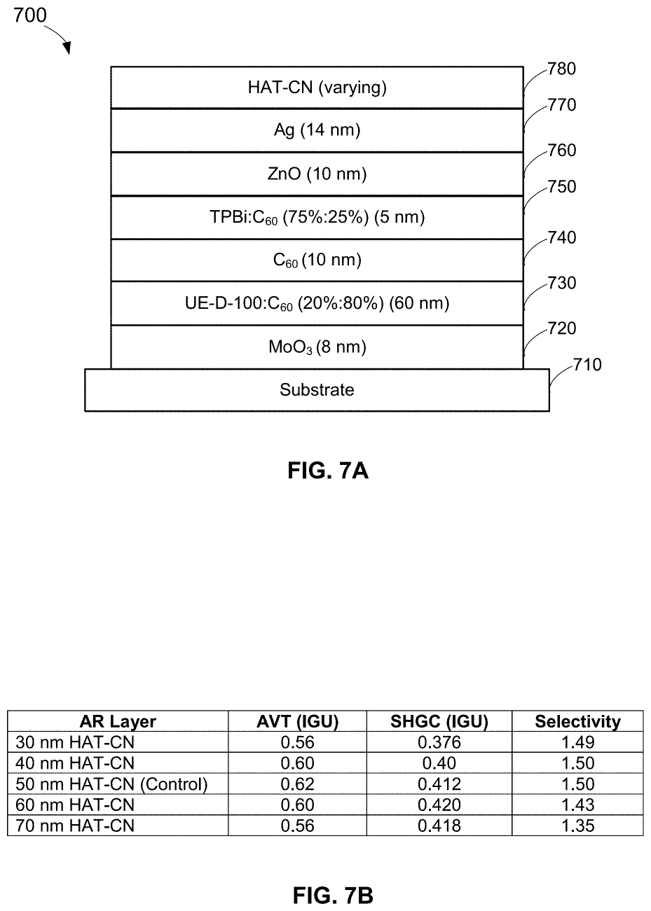

FIG. 7A illustrates examples of TPV devices 700 each including HAT-CN as a transparent AR layer having a different respective thickness according to certain embodiments. Each TPV device 700 may be an example of visibly transparent photovoltaic device 500 and may include a substrate 710 and multiple layers formed on substrate 710. For example, an HTL layer 720 of TPV device 700 may be similar to HTL layer 520 and may include a thin MoO₃ layer. A layer 770 of TPV device 700 may be an example of silver layer 560 and may be used as a cathode. A layer 760 of TPV device 700 may be an example of ZnO layer 550, and may also be used as an ETL layer, such as ETL layer 540. A layer 780 may be an example of optical layer 570 and may include an antireflection layer for visible light.

In the examples shown in FIG. 7A, the active layers may include a UE-D-100:C₆₀bulk heterojunction (BHJ) layer 730, a buckminsterfullerene (C₆₀) layer 740 (e.g., used as an electron acceptor), and a TPBi:C₆₀ transport layer 750. UE-D-100:C₆₀ layer 730 may include UE-D-100 as an electron donor and C₆₀ as an electron acceptor, where UE-D-100 and C₆₀ may be blended to form a mixture or may be in different layers. A TPBi:C₆₀ buffer layer 750 may include TPBi as a wide-bandgap host and C₆₀ as an electron transport material, where TPBi and C₆₀ may be in a mixture or may be in different layers. In some examples, UE-D-100:C₆₀ layer 730 and TPBi:C₆₀ layer 750 may have a ratio of, for example, about 20:80 and about 75:25 by volume, respectively.

Layer 780 may be an optical layer and/or an encapsulating layer for the cathode (e.g., layer 770). In the examples shown in FIG. 7A, layer 780 may include HAT-CN as a transparent OAR layer. In different TPV devices 700 shown in FIG. 7A, layer 780 may have different respective thicknesses, such as between about 30 nm and about 70 nm. As shown in FIG. 6, HAT-CN may have an absorption peak in the UV band and very low absorptance in the visible and NIR bands, rendering it transparent.

FIG. 7B illustrates simulated performance of the examples of TPV devices shown in FIG. 7A in an IGU construction as shown in FIG. 4A, according to certain embodiments. The performance parameters shown in FIG. 7B may include, for example, AVT, SHGC, and selectivity. In some simulations described in this disclosure, the WINDOW code by Lawrence Berkeley National Lab may be used to calculate the optical and thermal properties of IGUs according various embodiments in this disclosure. As shown by FIG. 7B, varying the thickness of the HAT-CN layer may not improve the AVT beyond 0.62 and the selectivity above 1.5 for device structure 700. A highest AVT and selectivity may be achieved when the thickness of the HAT-CN layer (e.g., layer 780) is about 50 nm. Thus, in many embodiments described below, the TPV device with a 50-nm HAT-CN layer may be used as the control or reference device for performance comparison due to the relatively high AVT and selectivity values achieved with this HAT-CN layer thickness and the fact that it exhibits no NIR absorption.

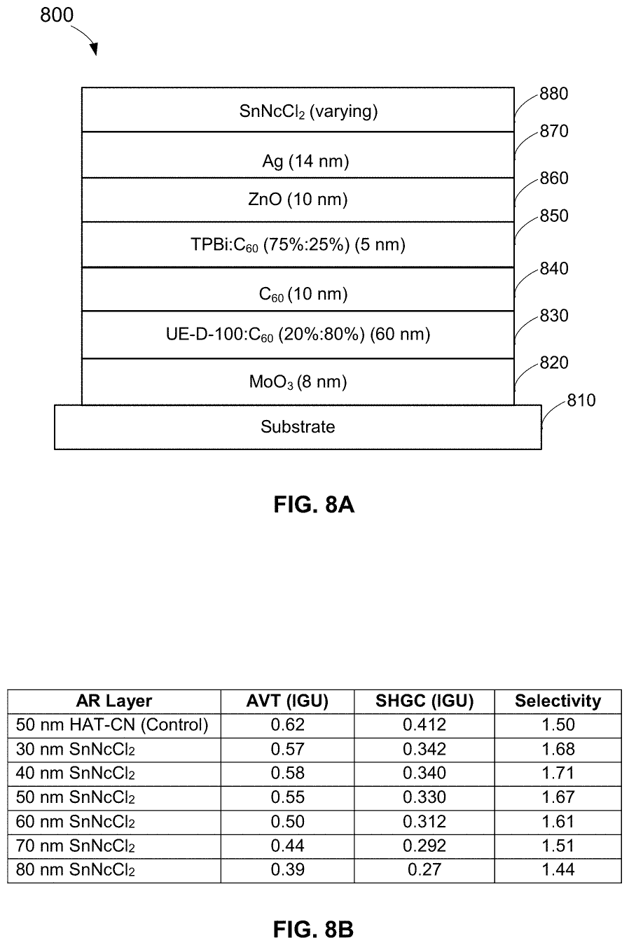

FIG. 8A illustrates examples of TPV devices 800 each including SnNcCl₂ as a selective NIR absorbing AR layer having a different respective thickness according to certain embodiments. As TPV devices 700, TPV devices 800 may each be an example of visibly transparent photovoltaic device 500 and may include a substrate 810 and multiple layers formed on substrate 810. For example, a layer 820 of TPV device 800 may be an HTL layer, such as HTL layer 720, and may include a thin MoO₃ layer. A layer 870 of TPV device 800 may be a silver layer similar to layer 770 and may be used as a cathode. A layer 860 of TPV device 800 may include a ZnO layer similar to layer 760 and may also be used as an ETL layer. The active layers may include a UE-D-100:C₆₀ layer 830 and a C₆₀ layer 840, which may be similar to UE-D-100:C₆₀ layer 730 and C₆₀ layer 740, respectively. Each TPV device 800 may also include a TPBi:C₆₀ layer 850, which may be a buffer layer as TPBi:C₆₀ layer 750 in TPV device 700.

An optical layer 880 may be an example of optical layer 570 and may include an AR layer for visible light. In the examples shown in FIG. 8A, optical layer 880 may include a NIR absorbing SnNcCl₂ layer as the optical AR layer for visible light, rather than a transparent HAT-CN layer as in layer 780. In different TPV devices 800 shown in FIG. 8A, optical layers 880 may have different respective thicknesses, such as between about 30 nm and about 80 nm. As shown in FIG. 6, SnNcCl₂ may have an absorption peak in the NIR band and very low absorptance in the visible band.

FIG. 8B illustrates simulated performance of the examples of TPV devices 800 shown in FIG. 8A in an IGU construction as shown in FIG. 4A, according to certain embodiments. The examples of TPV devices 800 may include optical layers 880 of different thicknesses. Each optical layer 880 may include selective NIR absorbing SnNcCl₂ materials. The performance parameters shown in FIG. 8B may include, for example, AVT, SHGC, and selectivity. As shown by FIG. 8B, varying the thickness of optical layer 880 may reduce the SHGC and increase the selectivity. A higher AVT and selectivity may be achieved when the thickness of the SnNcCl₂ material layer (e.g., optical layer 880) is between about 30 nm and about 50 nm. For example, the selectivity of TPV devices 800 may improve to about 1.67-1.71, a significant improvement over TPV devices 700, while maintaining a comparable AVT (e.g., above 0.55), when the thickness of the SnNcCl₂ material layer is between about 30 nm and about 50 nm.

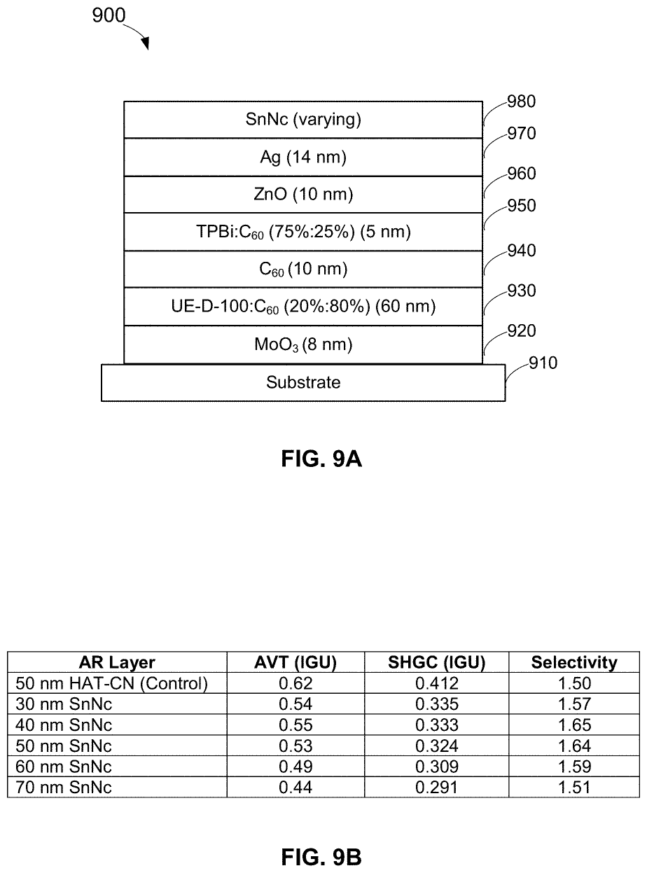

FIG. 9A illustrates examples of TPV devices 900 each including SnNc as a selective NIR absorbing AR layer having a different respective thickness according to certain embodiments. As in TPV devices 700, TPV devices 900 may each be an example of visibly transparent photovoltaic device 500 and may include a substrate 910 and multiple layers formed on substrate 910. For example, a layer 920 of TPV device 900 may be an HTL layer, such as HTL layer 720, and may include a thin MoO₃ layer. A layer 970 of TPV device 900 may be a silver layer similar to layer 770 and may be used as a cathode. A layer 960 of TPV device 900 may include a ZnO layer similar to layer 760 and may also be used as an ETL layer. The active layers may include a UE-D-100:C₆₀ layer 930 and a C₆₀ layer 940, which may be similar to UE-D-100:C₆₀ layer 730 and C₆₀ layer 740, respectively. Each TPV device 900 may also include a TPBi:C₆₀ layer 950, which may be a buffer layer as TPBi:C₆₀ layer 750 in TPV device 700.

An optical layer 980 may be an example of optical layer 570 and may include an AR layer for visible light. In the examples shown in FIG. 9A, optical layer 980 may include a NIR absorbing SnNc layer as the optical AR layer for visible light, rather than a transparent HAT-CN layer as layer 780. In different TPV devices 900 shown in FIG. 9A, optical layers 980 may have different respective thicknesses, such as between about 30 nm and about 70 nm. As shown in FIG. 6, SnNc may have a high absorption peak in the NIR band and low absorptance in the visible band.

FIG. 9B illustrates simulated performance of the examples of TPV devices 900 shown in FIG. 9A in an IGU construction as shown in FIG. 4A, according to certain embodiments. The examples of TPV devices 900 may include optical layers 980 of different thicknesses. Each optical layer 980 may include selective NIR absorbing SnNc material of varying thickness. The performance parameters shown in FIG. 9B may include, for example, AVT, SHGC, and selectivity. As shown by FIG. 9B, varying the thickness of optical layer 980 may reduce the SHGC and increase the selectivity. A higher AVT and selectivity may be achieved when the thickness of the SnNc material layer (e.g., optical layer 980) is between about 40 nm and about 50 nm. For example, the selectivity of TPV devices 900 may improve to about 1.65, a significant improvement over TPV devices 700, while maintaining a comparable AVT (e.g., about 0.55), when the thickness of the SnNc material layer is about 40 nm.

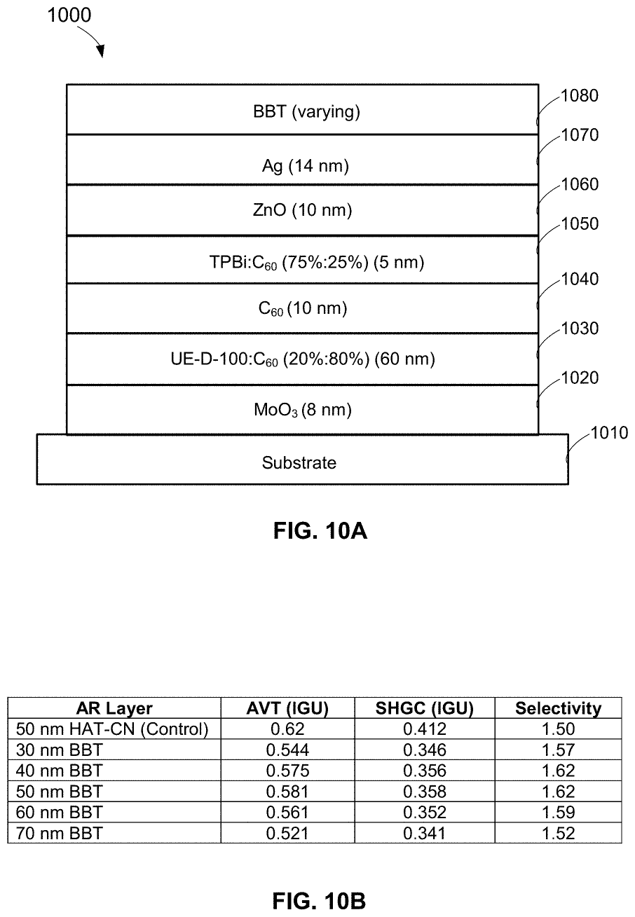

FIG. 10A illustrates examples of TPV devices 1000 each including BBT as a selective NIR absorbing AR layer having a different respective thickness according to certain embodiments. As in TPV devices 700, TPV devices 1000 may each be an example of visibly transparent photovoltaic device 500 and may include a substrate 1010 and multiple layers formed on substrate 1010. For example, a layer 1020 of TPV device 1000 may be an HTL layer, such as HTL layer 720, and may include a thin MoO₃ layer. A layer 1070 of TPV device 1000 may be a silver layer similar to layer 770 and may be used as a cathode. A layer 1060 of TPV device 1000 may include a ZnO layer similar to layer 760 and may also be used as an ETL layer. The active layers may include a UE-D-100:C₆₀ layer 1030 and a C₆₀ layer 1040, which may be similar to UE-D-100:C₆₀ layer 730 and C₆₀ layer 740, respectively. Each TPV device 1000 may also include a TPBi:C₆₀ layer 1050, which may be a buffer layer as TPBi:C₆₀ layer 750 in TPV device 700.

An optical layer 1080 may be an example of optical layer 570 and may include an AR layer for visible light. In the examples shown in FIG. 10A, optical layer 1080 may include a NIR absorbing BBT layer as the optical AR layer for visible light, rather than a transparent HAT-CN layer as layer 780. In different TPV devices 1000 shown in FIG. 10A, optical layers 1080 may have different respective thicknesses, such as between about 30 nm and about 70 nm. As shown in FIG. 6, BBT may have a lower absorption peak in the NIR band than SnNc and SnNcCl₂ and a low absorptance in the visible band.

FIG. 10B illustrates simulated performance of the examples of TPV devices 1000 shown in FIG. 10A in an IGU construction as shown in FIG. 4A, according to certain embodiments. The examples of TPV devices 1000 may include optical layers 1080 of different thicknesses. Each optical layer 1080 may include selective NIR absorbing BBT material. The performance parameters shown in FIG. 10B may include, for example, AVT, SHGC, and selectivity. As shown by FIG. 10B, varying the thickness of optical layer 1080 may reduce the SHGC and increase the selectivity. A higher AVT and selectivity may be achieved when the thickness of the BBT material layer (e.g., optical layer 1080) is between about 40 nm and about 50 nm. For example, the selectivity of TPV devices 1000 may be about 1.62, an improvement over TPV devices 700, while maintaining a comparable AVT (e.g., about 0.58), when the thickness of the BBT material layer is about 50 nm.

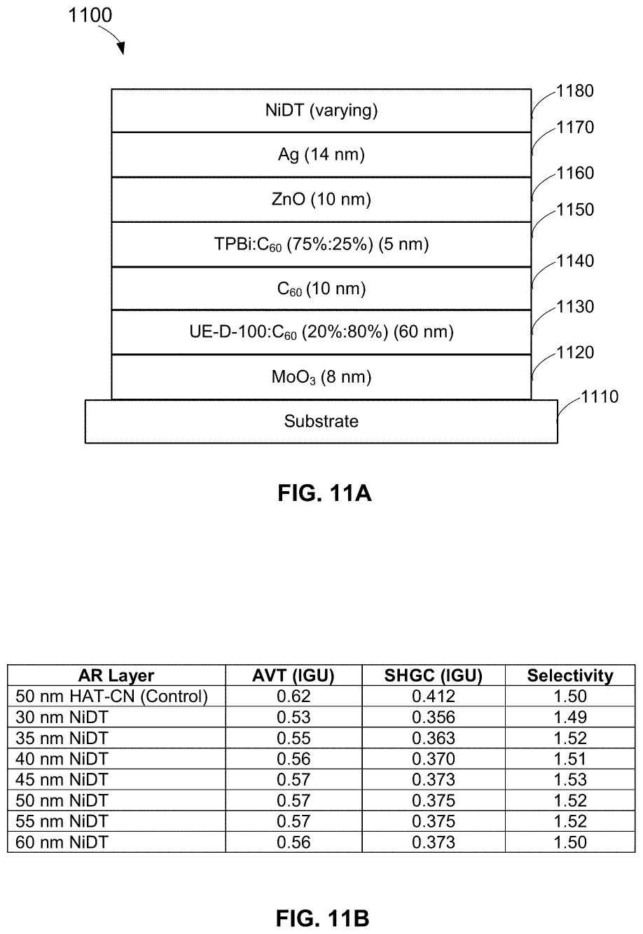

FIG. 11A illustrates examples of TPV devices 1100 each including NiDT as a selective NIR absorbing AR layer having a different respective thickness according to certain embodiments. As TPV devices 700, TPV devices 1100 may each be an example of visibly transparent photovoltaic device 500 and may include a substrate 1110 and multiple layers formed on substrate 1110. For example, a layer 1120 of TPV device 1100 may be an HTL layer, such as HTL layer 720, and may include a thin MoO₃ layer. A layer 1170 of TPV device 1100 may be a silver layer similar to layer 770 and may be used as a cathode. A layer 1160 of TPV device 1100 may include a ZnO layer similar to layer 760 and may also be used as an ETL layer. The active layers may include a UE-D-100:C₆₀ layer 1130 and a C₆₀ layer 1140, which may be similar to UE-D-100:C₆₀ layer 730 and C₆₀ layer 740, respectively. Each TPV device 1100 may also include a TPBi:C₆₀ layer 1150, which may be a buffer layer as TPBi:C₆₀ layer 750 in TPV device 700.

An optical layer 1180 may be an example of optical layer 570 and may include an AR layer for visible light. In the examples shown in FIG. 11A, optical layer 1180 may include a NIR absorbing NiDT layer as the optical AR layer for visible light, rather than a transparent HAT-CN layer as layer 780. In different TPV devices 1100 shown in FIG. 11A, optical layers 1180 may have different respective thicknesses, such as between about 30 nm and about 60 nm. As shown in FIG. 6, NiDT may have a low absorption peak in the NIR band and low absorptance in the visible band.

FIG. 11B illustrates simulated performance of the examples of TPV devices 1100 shown in FIG. 11A in an IGU construction as shown in FIG. 4A, according to certain embodiments. The examples of TPV devices 1100 may include optical layers 1180 of different thicknesses. Each optical layer 1180 may include selective NIR absorbing NiDT materials. The performance parameters shown in FIG. 11B may include, for example, AVT, SHGC, and selectivity. As shown by FIG. 11B, varying the thickness of optical layer 1180 may not significantly reduce the SHGC or increase the AVT or selectivity due to the lower NIR absorption and low visible absorption of NiDT. While NiDT has a comparable peak extinction coefficient as BBT in the NIR, its NIR absorption is relatively narrowband. This may result in insufficient NIR absorption at the optimal thicknesses for visible transmission compared with the transparent HAT-CN control. For example, when the thickness of the NiDT material layer is about 50 nm (e.g., 45 nm), the selectivity of TPV device 1100 may be about 1.53 and the AVT may be about 0.57. In comparison, when the thickness of optical layer 780 including HAT-CN is about 50 nm, the selectivity of TPV device 700 may be about 1.50 and the AVT may be about 0.62. Therefore, incorporating NiDT in optical layer 1180 may not significantly improve the selectivity of TPV devices 1100.

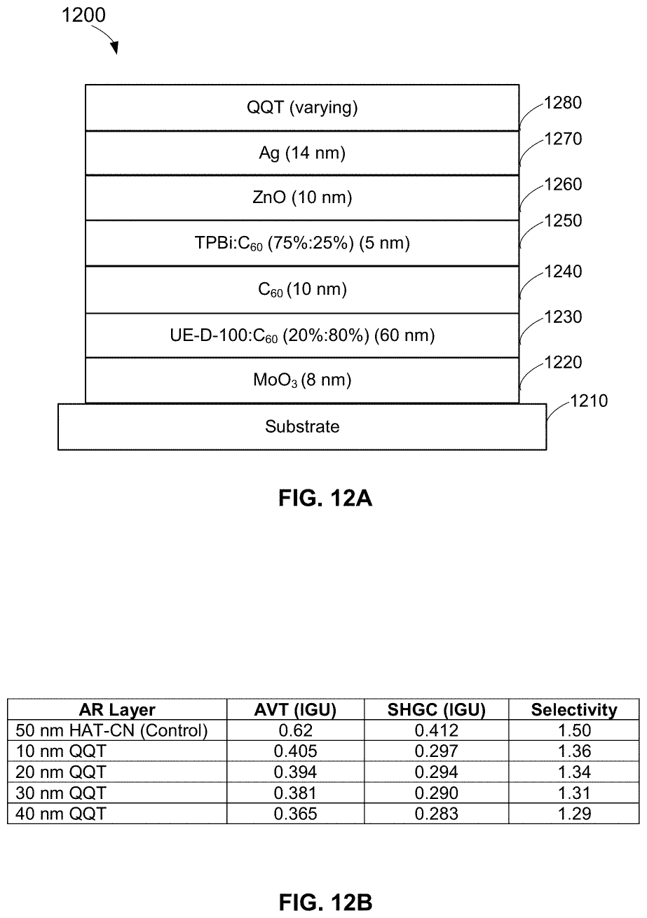

FIG. 12A illustrates examples of TPV devices 1200 each including QQT as a selective NIR absorbing AR layer having a different respective thickness according to certain embodiments. As TPV devices 700, TPV devices 1200 may each be an example of visibly transparent photovoltaic device 500 and may include a substrate 1210 and multiple layers formed on substrate 1210. For example, a layer 1220 of TPV device 1200 may be an HTL layer, such as HTL layer 720, and may include a thin MoO₃ layer. A layer 1270 of TPV device 1200 may be a silver layer similar to layer 770 and may be used as a cathode. A layer 1260 of TPV device 1200 may include a ZnO layer similar to layer 760 and may also be used as an ETL layer. The active layers may include a UE-D-100:C₆₀ layer 1230 and a C₆₀ layer 1240, which may be similar to UE-D-100:C₆₀ layer 730 and C₆₀ layer 740, respectively. Each TPV device 1200 may also include a TPBi:C₆₀ layer 1250, which may be a buffer layer as TPBi:C₆₀ layer 750 in TPV device 700.

An optical layer 1280 may be an example of optical layer 570 and may include an AR layer for visible light. In the examples shown in FIG. 12A, optical layer 1280 may include a NIR absorbing QQT layer, rather than a transparent HAT-CN layer as layer 780, as the optical AR layer for visible light. In different TPV devices 1200 shown in FIG. 12A, optical layers 1280 may have different respective thicknesses, such as between about 10 nm and about 40 nm. As shown in FIG. 6, QQT may have high absorptance in at least a portion of the visible band and the NIR band.

FIG. 12B illustrates simulated performance of the examples of TPV devices 1200 shown in FIG. 12A in an IGU construction as shown in FIG. 4A, according to certain embodiments. The examples of TPV devices 1200 may include optical layers 1280 of different thicknesses. Each optical layer 1280 may include selective NIR absorbing QQT materials. The performance parameters shown in FIG. 12B may include, for example, AVT, SHGC, and selectivity. As shown by FIG. 12B, varying the thickness of optical layer 1280 may reduce the SHGC as well as the selectivity. The use of QQT may decrease the SHGC of the TPV devices due to its NIR absorption but may also significantly decrease the AVT due to its strong visible absorption. This highlights the need for selective NIR absorbers with minimal visible absorption to maximize gains in selectivity. For example, when the thickness of the QQT material layer is about 10 nm, the selectivity of TPV devices 1200 may be only about 1.36 and the AVT may be only about 0.4. In comparison, when the thickness of optical layer 780 including HAT-CN is about 50 nm, the selectivity of TPV device 700 may be about 1.50 and the AVT may be about 0.62. Therefore, incorporating QQT in optical layer 1280 may not improve the selectivity.

FIGS. 11A-12B show that, to improve the selectivity, materials with selective NIR absorption and very little or no visible absorption could be used. Materials that absorb in both the NIR and visible bands are not selectively NIR absorbing. This may reduce the SHGC, but may also significantly reduce the AVT, and thus may not improve the selectivity of the TPV devices. Similarly, for selectivity gains to be realized in the case of NIR absorbing AR layers, the extinction coefficient in the NIR may need to be sufficiently large or broadband such that the SHGC is reduced at layer thicknesses with maximized AVT.

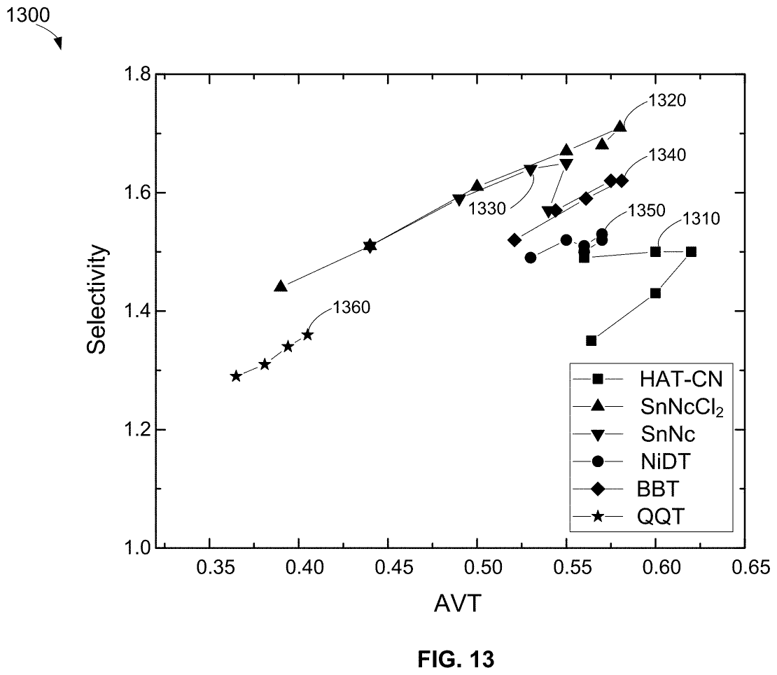

FIG. 13 illustrates the AVT and selectivity trends as a function of AR layer thickness for examples of TPV devices including various materials in the AR layers according to certain embodiments. FIG. 13 includes scatter plots of the data shown in FIGS. 7B, 8B, 9B, 10B, 11B, and 12B. In each case, there may be an AR layer thickness at which the selectivity and AVT are simultaneously maximized. For example, data points on curve 1310 correspond to data points for TPV devices including HAT-CN as the AR layer, as shown in FIG. 7B. Curve 1310 shows that high AVT values may be achieved using HAT-CN in the AR layers, however the selectivity values may be limited. The highest selectivity is achieved at a thickness where the AVT is maximized; above and below this thickness, the AVT and selectivity simultaneously drop.

Data points on curve 1320 correspond to TPV devices using SnNcCl₂ as the AR layer, as shown in FIG. 8B. Curve 1320 shows that higher selectivity values and similarly high AVT values may be achieved using SnNcCl₂ as an NIR absorbing AR layer as compared to devices using HAT-CN as a transparent AR layer. This can be visualized by a vertical shift of the selectivity-AVT curve 1320 relative to curve 1310 for the transparent AR layer. The highest selectivity is achieved at a thickness where the AVT is maximized; above and below this thickness, the AVT and selectivity simultaneously drop.

Data points on curve 1330 correspond to TPV devices using SnNc as the AR layer, as shown in FIG. 9B. Curve 1330 follows a similar trend to curve 1320 due to the similar extinction coefficients of SnNc and SnNcCl₂, as seen in FIG. 6. However, the maximum achievable AVT for TPV devices using SnNc as the AR layer is lower than those using SnNcCl₂, thus the highest selectivity and AVT of curve 1330 are slightly reduced relative to curve 1320. Curve 1330 shows that higher selectivity values and similarly high AVT values may be achieved using SnNc as an NIR absorbing AR layer as compared to devices using HAT-CN as a transparent AR layer. This can be visualized by a vertical shift of the selectivity-AVT curve 1330 relative to curve 1310 for the transparent AR layer. The highest selectivity is achieved at a thickness where the AVT is maximized; above and below this thickness, the AVT and selectivity simultaneously drop.

Data points on curve 1340 correspond to TPV devices using BBT as the AR layer, as shown in FIG. 10B. Curve 1340 shows that higher selectivity values and similarly high AVT values may be achieved using BBT as an NIR absorbing AR layer as compared to devices using HAT-CN as a transparent AR layer. Due to the lower extinction coefficient of BBT in the NIR relative to SnNcCl₂ as shown in FIG. 6, the SHGC at maximum AVT is higher for TPV devices using BBT as an AR layer. Thus, the peak selectivity of curve 1340 is lower than that of curve 1320. However, curve 1340 still shows that higher selectivity values and similarly high AVT values may be achieved using BBT as an NIR absorbing AR layer as compared to devices using HAT-CN as a transparent AR layer. This can be visualized by a vertical shift of the selectivity-AVT curve 1340 relative to curve 1310 for the transparent AR layer. The highest selectivity is achieved at a thickness where the AVT is maximized; above and below this thickness, the AVT and selectivity simultaneously drop.

Data points on curve 1350 correspond to TPV devices using NiDT as the AR layer, as shown in FIG. 11B. Curve 1350 shows that comparable selectivity values at lower AVT values may be achieved using NiDT as an NIR absorbing AR layer as compared to devices using HAT-CN as a transparent AR layer. Due to the relatively low and narrowband extinction coefficient of NiDT in the NIR as shown in FIG. 6, there is an insufficient amount of NIR absorption at the optimal layer thickness for visible transmission to significantly reduce the SHGC. As a result, the selectivity does not show improvement over the transparent HAT-CN control, and there is no vertical shift of the selectivity-AVT curve for 1350 relative to curve 1310. The highest selectivity is still achieved at a thickness where the AVT is maximized; above and below this thickness, the AVT and selectivity simultaneously drop.

Data points on curve 1360 correspond to TPV devices using QQT as the AR layer, as shown in FIG. 12B. Curve 1360 shows that, compared with TPV devices with HAT-CN as the AR layer, both the selectivity and the AVT values may be significantly reduced using QQT as the AR layer. Thus, incorporating QQT or other materials that do not selectively absorb NIR light with visible light absorption into TPV devices may not achieve the desired high AVT and high selectivity.

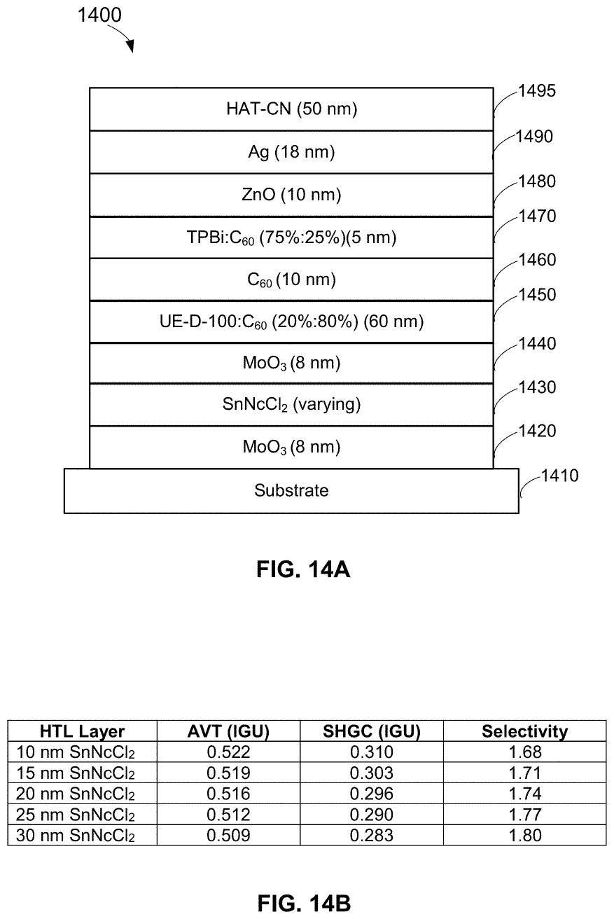

FIG. 14A illustrates examples of TPV devices 1400 each including a selective NIR absorbing material having a different respective thickness in an HTL layer according to certain embodiments. Similar to TPV devices 700, TPV devices 1400 may each include a substrate 1410 and multiple layers formed on substrate 1410. For example, a layer 1490 of TPV device 1400 may be a silver layer similar to layer 770 and may be used as a cathode. A layer 1480 of TPV device 1400 may include a ZnO layer similar to layer 760 and may also be used as an ETL layer. An optical layer 1495 may include an antireflection layer for visible light and may include, for example, a HAT-CN layer with a thickness 50 nm. The active layers may include a UE-D-100:C₆₀ layer 1450 and a C₆₀ layer 1460, which may be similar to UE-D-100:C₆₀ layer 730 and C₆₀ layer 740, respectively. Each TPV device 1400 may also include a TPBi:C₆₀ buffer layer 1470.

In the examples shown in FIG. 14A, a SnNcCl₂ layer 1430 may be inserted as part of the HTL layer, which may include a thin MoO₃ layer 1420 and a thin MoO₃ layer 1440 that sandwich SnNcCl₂ layer 1430. In different TPV devices 1400 shown in FIG. 14A, SnNcCl₂ layers 1430 may have different respective thicknesses, such as between about 10 nm and about 30 nm. As described above, SnNcCl₂ has an absorption peak in the NIR band and very low absorptance in the visible band and thus is a selective NIR absorbing material. In some embodiments, SnNcCl₂ layer 1430 may be mixed with MoO₃ or other materials.

FIG. 14B illustrates simulated performance of the examples of TPV devices 1400 shown in FIG. 14A in an IGU construction as shown in FIG. 4A, according to certain embodiments. Each TPV device 1400 may include a SnNcCl₂ layer 1430 of a different respective thickness. SnNcCl₂ layer 1430 may be considered as part of the HTL layer in each TPV device 1400. The performance parameters shown in FIG. 14B include AVT, SHGC, and selectivity. As shown by FIG. 14B, incorporating SnNcCl₂ layer 1430 in the HTL layer may reduce the SHGC and increase the selectivity, even though the AVT may decrease slightly. This is due to the selective absorption of NIR light by the SnNcCl₂ HTL, which causes a larger reduction in SHGC over AVT with increasing thickness. For example, the selectivity of TPV devices 1400 may improve to about 1.8 (compared with about 1.5 for TPV device 700) with the AVT greater than 0.5, when the thickness of SnNcCl₂ layer 1430 is about 30 nm. Thus, incorporating selective NIR absorbing materials in other layers of the TPV device may also improve the SHGC and selectivity of the TPV device.

In some embodiments, the SHGC and selectivity of the TPV device can be further improved by changing the thickness of a metal layer, such as layer 770 that may include a silver layer and may be used as an electrode. Increasing the thickness of the metal layer may reduce the SHGC but may also concomitantly decrease the AVT. Thus, the thickness of the metal layer may be selected to improve the selectivity while maintaining a relatively high AVT. In some embodiments where the selective NIR absorbing material layer (e.g., SnNcCl₂ layer 1430) may be closer to the substrate (e.g., substrate 1410) than the metal layer (e.g., layer 1490) as shown in FIG. 14, the NIR light reflected by the metal layer may reach the selective NIR absorbing material layer again and be absorbed. Therefore, a thinner selective NIR absorbing material layer may be used to achieve comparable SHGC, AVT, and selectivity performance compared to TPV devices having a thicker selective NIR absorbing material layer in the optical AR layer (e.g., optical layer 880 or 980).

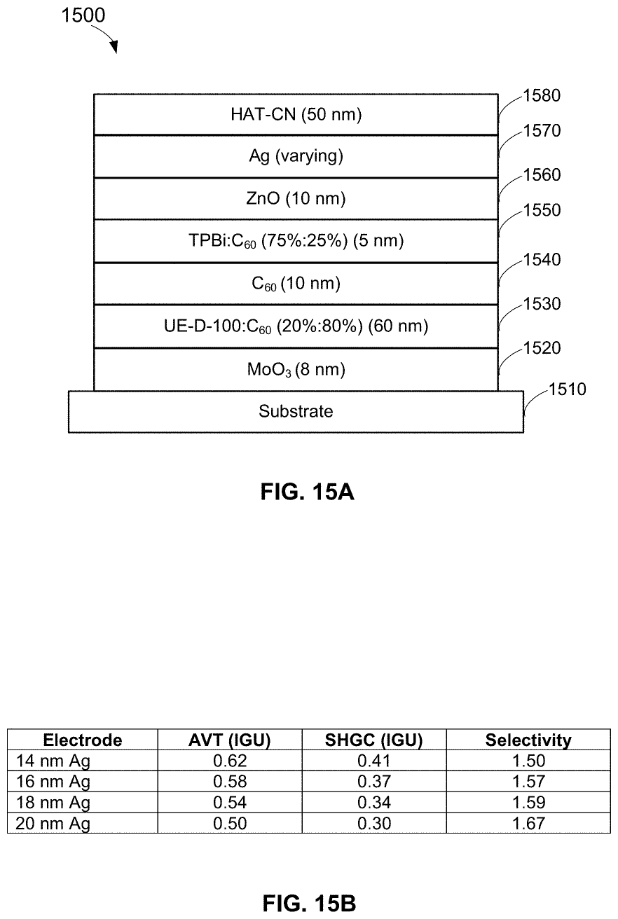

FIG. 15A illustrates examples of TPV devices 1500 each including a metal layer of a different respective thickness according to certain embodiments. TPV devices 1500 may be similar to TPV device 700, where a substrate 1510 may be similar to substrate 710 and a plurality of layers 1520-1580 on substrate 1510 may be similar to layers 720-780. For example, layer 1520 of TPV device 1500 may be an HTL layer, such as HTL layer 720, and may include a thin MoO₃ layer. Layer 1570 of TPV device 1500 may be a silver layer similar to layer 770 and may be used as a cathode. A thin metal layer, such as a thin silver layer, may remain semitransparent to visible light while preferentially reflecting NIR light. The thickness of layer 1570 in TPV devices 1500 shown in FIG. 15A may vary from about 14 nm to about 20 nm. A layer 1560 of TPV device 1500 may include a ZnO layer similar to layer 760 and may also be used as an ETL layer. The active layers may include a UE-D-100:C₆₀ layer 1530 and a C₆₀ layer 1540, which may be similar to UE-D-100:C₆₀ layer 730 and C₆₀ layer 740, respectively. TPBi:C₆₀ layer 1550 may be a buffer layer. An optical layer 1580 may include an AR layer (e.g., a HAT-CN layer with a thickness 50 nm) for reducing the reflection of visible light at the interface between TPV device 1500 and the ambient environment (e.g. air, Ar, or vacuum). The thickness of the transparent HAT-CN AR layer is fixed at 50 nm, which is shown to be the optimal thickness for AVT and selectivity according to FIGS. 7B and 13.

FIG. 15B illustrates simulated performance of TPV devices 1500 shown in FIG. 15A in an IGU construction as shown in FIG. 4A, according to certain embodiments. The performance parameters shown in FIG. 15B include AVT, SHGC, and selectivity. As shown by FIG. 15B, increasing the thickness of the metal layer (e.g., layer 1570) may reduce the SHGC and increase the selectivity, but it may also concomitantly reduce the AVT. For example, the selectivity of TPV devices 1500 may improve to about 1.67, while maintaining an AVT value above 0.5, when the thickness of the silver layer is about 20 nm.

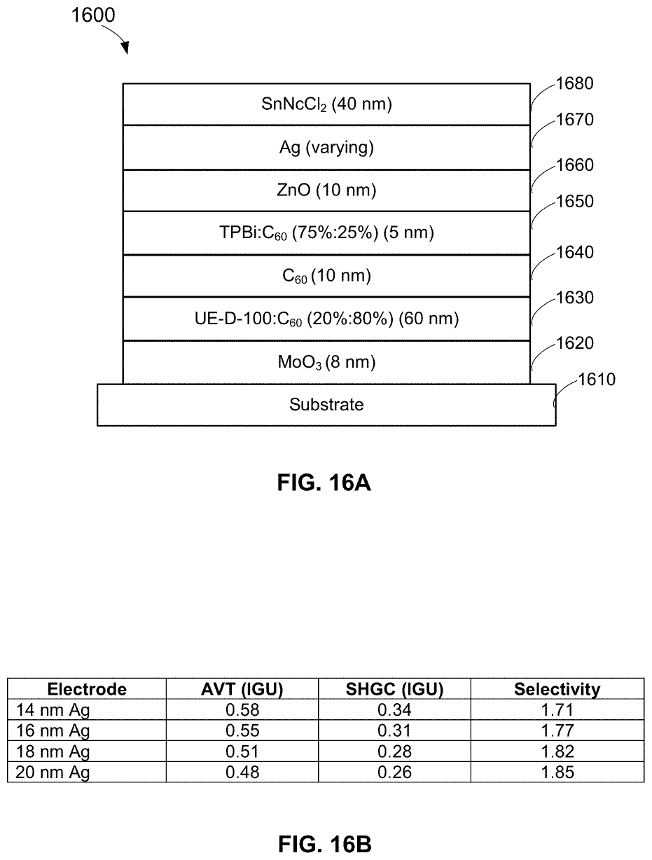

FIG. 16A illustrates examples of TPV devices 1600 each including SnNcCl₂ as a selective NIR absorbing AR layer and a metal layer of a different respective thickness according to certain embodiments. The thickness of the SnNcCl₂ layer is fixed at 40 nm, which is shown to be the optimal thickness for AVT and selectivity according to FIGS. 8B and 13. The TPV devices 1600 may be similar to TPV device 700, where a substrate 1610 may be similar to substrate 710 and a plurality of layers 1620-1680 on substrate 1610 may be similar to layers 720-780. For example, layer 1620 of TPV device 1600 may be an HTL layer, such as HTL layer 720, and may include a thin MoO₃ layer. Layer 1670 of TPV device 1600 may be a silver layer similar to layer 770 and may be used as a cathode. A thin metal layer, such as a thin silver layer, may remain semitransparent to visible light while preferentially reflecting NIR light. The thickness of layer 1670 in TPV devices 1600 shown in FIG. 16A may vary from about 14 nm to about 20 nm. A layer 1660 of TPV device 1600 may include a ZnO layer similar to layer 760 and may also be used as an ETL layer. The active layers may include a UE-D-100:C₆₀ layer 1630 and a C₆₀ layer 1640, which may be similar to UE-D-100:C₆₀ layer 730 and C₆₀ layer 740, respectively. TPBi:C₆₀ layer 1650 may be a buffer layer. An optical layer 1680 may include an AR layer for reducing the reflection of visible light at the interface between TPV device 1600 and the ambient environment (e.g. air, Ar, or vacuum).

FIG. 16B illustrates the simulated performance of TPV devices 1600 shown in FIG. 16A in an IGU construction as shown in FIG. 4A, according to certain embodiments. The performance parameters shown in FIG. 16B include AVT, SHGC, and selectivity. As shown by FIG. 16B, increasing the thickness of the metal layer (e.g., layer 1670) may reduce the SHGC and increase the selectivity, but it may also concomitantly reduce the AVT. At each silver layer thickness, the selectivity of TPV device 1600 may be higher than the selectivity of TPV device 1500. For example, the selectivity of TPV devices 1600 may improve to about 1.82, while maintaining an AVT value above 0.5, when the thickness of the silver layer is about 18 nm. Even though the selectivity may further increase with increasing silver layer thickness, further increase in the silver layer thickness may lead to the AVT less than about 50%.

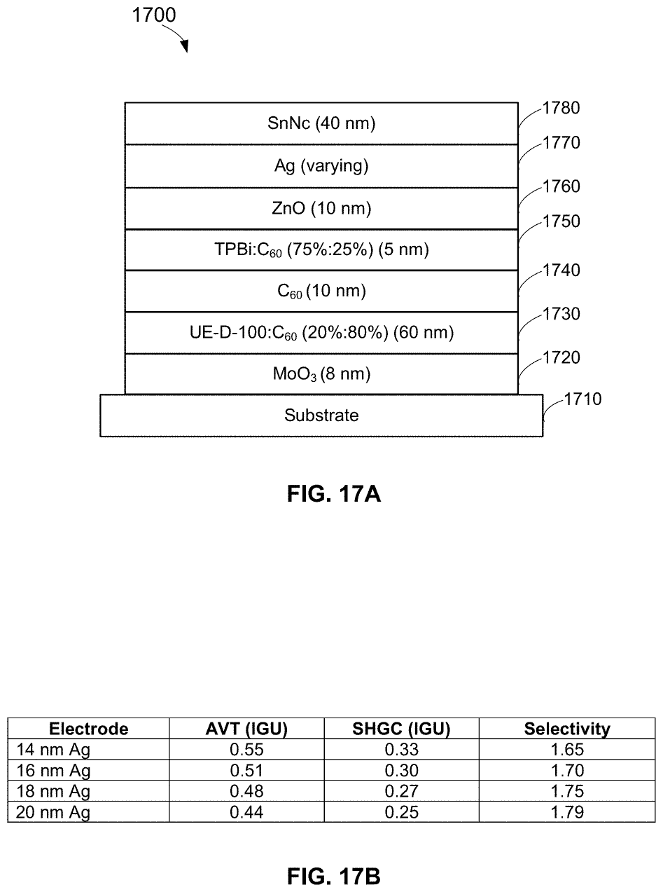

FIG. 17A illustrates examples of TPV devices 1700 each including SnNc as a selective NIR absorbing AR layer and a metal layer of a different respective thickness according to certain embodiments. The thickness of the SnNc layer is fixed at 40 nm, which is shown to be the optimal thickness for AVT and selectivity according to FIGS. 9B and 13. The TPV devices 1700 may be similar to TPV device 700, where a substrate 1710 may be similar to substrate 710 and a plurality of layers 1720-1780 on substrate 1710 may be similar to layers 720-780. For example, layer 1720 of TPV device 1700 may be an HTL layer, such as HTL layer 720, and may include a thin MoO₃ layer. Layer 1770 of TPV device 1700 may be a silver layer similar to layer 770 and may be used as a cathode. A thin metal layer, such as a thin silver layer, may remain semitransparent to visible light while preferentially reflecting NIR light. The thickness of layer 1770 in TPV devices 1700 shown in FIG. 17A may vary from about 14 nm to about 20 nm. A layer 1760 of TPV device 1700 may include a ZnO layer similar to layer 760 and may also be used as an ETL layer. The active layers may include a UE-D-100:C₆₀ layer 1730 and a C₆₀ layer 1740, which may be similar to UE-D-100:C₆₀ layer 730 and C₆₀ layer 740, respectively. TPBi:C₆₀ layer 1750 may be a buffer layer. An optical layer 1780 may include an AR layer for reducing the reflection of visible light at the interface between TPV device 1700 and the ambient environment (e.g. air, Ar, or vacuum).

FIG. 17B illustrates simulated performance of TPV devices 1700 shown in FIG. 17A in an IGU construction as shown in FIG. 4A, according to certain embodiments. The performance parameters shown in FIG. 17B include AVT, SHGC, and selectivity. As shown by FIG. 17B, increasing the thickness of the metal layer (e.g., layer 1770) may reduce the SHGC and increase the selectivity, but it will also concomitantly reduce the AVT. At each silver layer thickness, the selectivity of TPV device 1700 may be higher than the selectivity of TPV device 1500 but may be lower than the selectivity of TPV device 1600. For example, the selectivity of TPV device 1700 may be about 1.70 and the AVT of TPV device 1700 may be about 0.51, when the thickness of the silver layer is about 16 nm. Even though the selectivity may further increase with increasing silver layer thickness, further increase in the silver layer thickness may lead to the AVT less than about 50%.

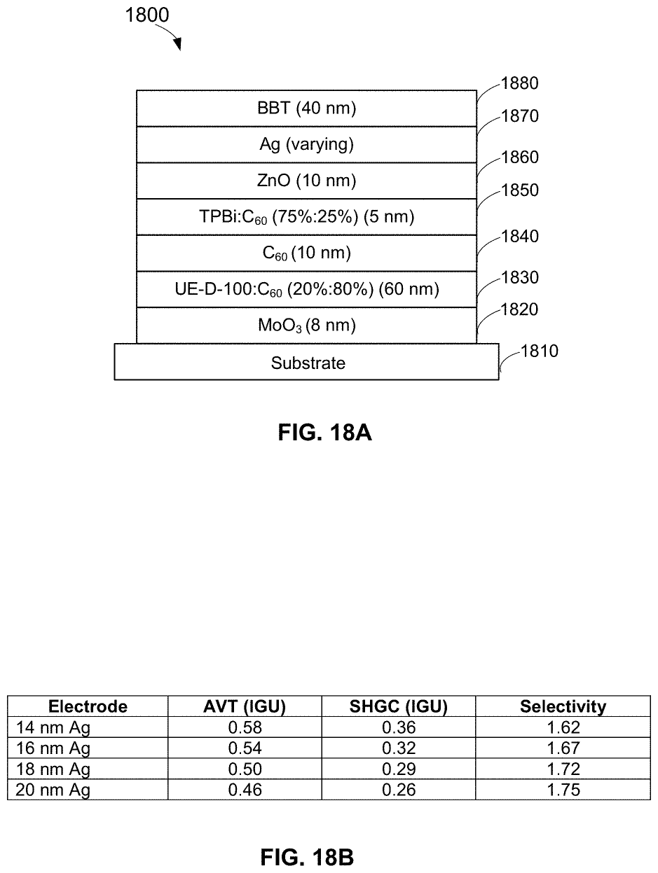

FIG. 18A illustrates examples of TPV devices 1800 each including BBT as a selective NIR absorbing AR layer and a metal layer of a different respective thickness according to certain embodiments. The thickness of the BBT layer is fixed at 40 nm, shown to be the optimal thickness for AVT and selectivity according to FIGS. 10B and 13. The TPV devices 1800 may be similar to TPV device 700, where a substrate 1810 may be similar to substrate 710 and a plurality of layers 1820-1880 on substrate 1810 may be similar to layers 720-780. For example, layer 1820 of TPV device 1800 may be an HTL layer, such as HTL layer 720, and may include a thin MoO₃ layer. Layer 1870 of TPV device 1800 may be a silver layer similar to layer 770 and may be used as a cathode. A thin metal layer, such as a thin silver layer, may remain semitransparent to visible light while preferentially reflecting NIR light. The thickness of layer 1870 in TPV devices 1800 shown in FIG. 18A may vary from about 14 nm to about 20 nm. A layer 1860 of TPV device 1800 may include a ZnO layer similar to layer 760 and may also be used as an ETL layer. The active layers may include a UE-D-100:C₆₀ layer 1830 and a C₆₀ layer 1840, which may be similar to UE-D-100:C₆₀ layer 730 and C₆₀ layer 740, respectively. TPBi:C₆₀ layer 1850 may be a buffer layer. An optical layer 1880 may include an AR layer for reducing the reflection of visible light at the interface between TPV device 1800 and the ambient environment (e.g. air, Ar, or vacuum).

FIG. 18B illustrates simulated performance of TPV devices shown in FIG. 18A in an IGU construction as shown in FIG. 4A, according to certain embodiments. The performance parameters shown in FIG. 18B include AVT, SHGC, and selectivity. As shown by FIG. 18B, increasing the thickness of the metal layer (e.g., layer 1870) may reduce the SHGC and increase the selectivity, but it may also concomitantly reduce the AVT. At each silver layer thickness, the selectivity of TPV device 1800 may be higher than the selectivity of TPV device 1500 but may be lower than the selectivity of TPV device 1600. For example, the selectivity of TPV device 1800 may be about 1.72 and the AVT of TPV device 1800 may be about 0.5 when the thickness of the silver layer is about 18 nm. Even though the selectivity may further increase with increasing silver layer thickness, further increasing the silver layer thickness beyond 18 nm may lead to the AVT less than about 50%.

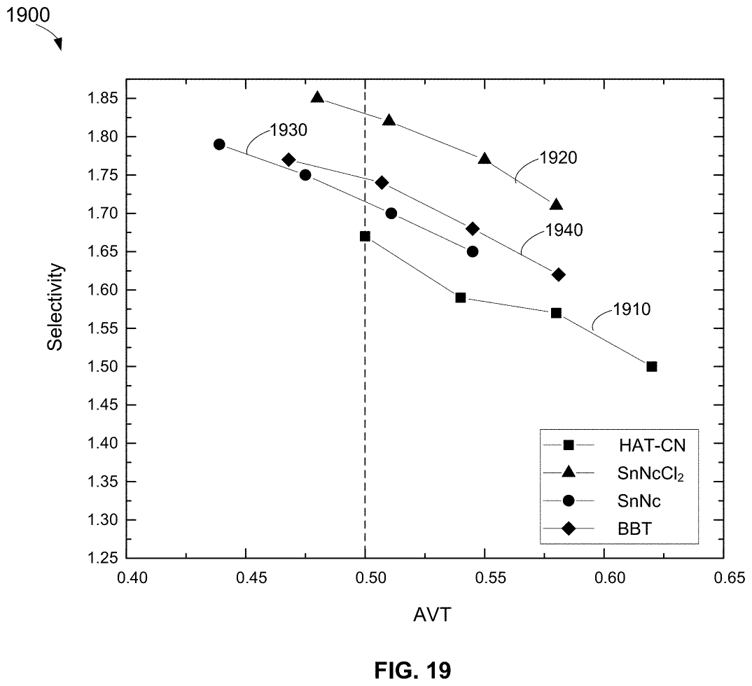

FIG. 19 illustrates AVT vs selectivity trends with varying metal layer thickness for TPV devices with different AR layer materials, according to certain embodiments. FIG. 19 includes scatter plots of the data shown in FIGS. 15B, 16B, 17B, and 18B. For example, data points on curve 1910 correspond to data points for TPV devices using HAT-CN in the AR layer, as shown in FIG. 15B. Data points on curve 1920 correspond to the data for TPV devices using SnNcCl₂ as the AR layer, as shown in FIG. 16B. Data points on curve 1930 correspond to data for TPV devices using SnNc as the AR layer, as shown in FIG. 17B. Data points on curve 1940 correspond to data for TPV devices using BBT as the AR layer, as shown in FIG. 18B.

FIG. 19 shows that increasing the metal layer thickness may yield a higher selectivity at the expense of a lower AVT. While using the transparent material HAT-CN as the AR layer achieves the highest AVT, the selectivity is the lowest of the examples shown for a given AVT value. For TPV devices containing selective NIR absorbers as the AR layer, there is a vertical shift of the selectivity-AVT curves relative to curve 1910 for the transparent AR layer. This can be understood as achieving higher selectivity values at a given AVT value. Of the examples shown, using SnNcCl₂ in the AR layer achieves the highest selectivity-AVT combination (shown by curve 1920), as SnNcCl₂ exhibits the largest extinction coefficients (strongest absorption) in the NIR while still maintaining negligible visible absorption (as shown in FIG. 6).

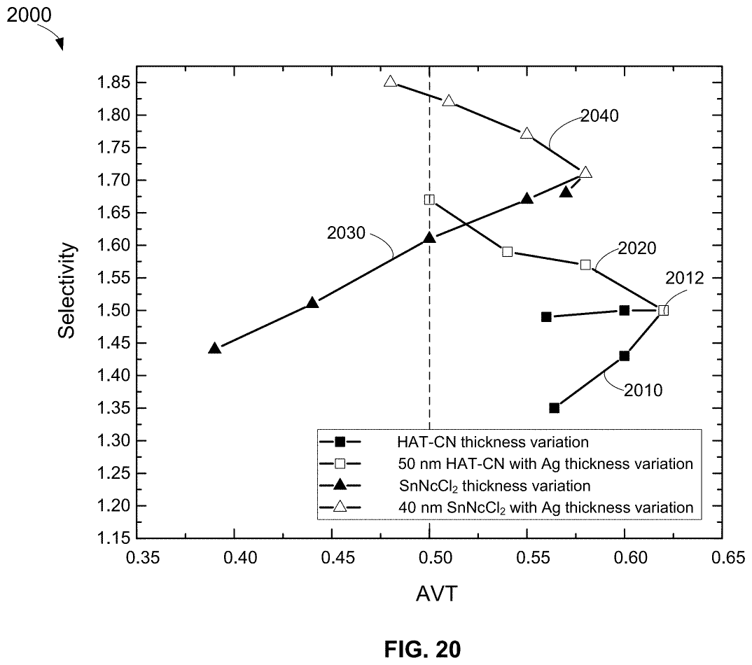

FIG. 20 illustrates techniques for improving the AVT and selectivity for TPV devices through variations in the metal and AR layers, according to certain embodiments. A curve 2010 may be similar to curve 1310 and may show the change in AVT and selectivity values with the change in the thickness of the HAT-CN AR layer. A curve 2020 may be similar to curve 1910 and may show the change in AVT and selectivity values with the change in the thickness of the metal layer (e.g., the silver cathode). Curve 2020 may start from a data point 2012 on curve 2010 at which the AVT and selectivity values are maximized. This corresponds to TPV devices having a silver layer of a certain thickness (e.g., about 14 nm) and an optical AR layer of different respective thickness, and may be generated by varying the thickness of the silver layer (e.g., from about 14 nm to about 20 nm) while keeping the thickness of the HAT-CN AR layer unchanged (e.g., at about 50 nm).

A curve 2030 may be similar to curve 1320 and may show the change in AVT and selectivity values with the change in the thickness of the SnNcCl₂ AR layer. A curve 2040 may be similar to curve 1920 and may show the change in AVT and selectivity values with the change in the thickness of the metal layer (e.g., the silver cathode). Curve 2040 may start from a data point 2032 on curve 2030 at which the AVT and selectivity values are maximized. This corresponds to TPV devices having a silver layer of a certain thickness (e.g., about 14 nm) and an AR layer of different respective thickness, and may be generated by varying the thickness of the silver layer (e.g., from about 14 nm to about 20 nm) while keeping the thickness of the SnNcCl₂ AR layer unchanged (e.g., at about 40 nm).

FIG. 20 shows that improving selectivity by increasing the silver layer thickness may yield a higher selectivity at the expense of a lower AVT. In contrast, using a NIR absorbing material (e.g., SnNcCl₂) in the AR layer may achieve both higher selectivity values and higher AVT values. The two techniques may be combined to achieve the desired AVT and selectivity by varying the thickness of the selective NIR absorbing layer and varying the thickness of the metal layer to select the optimum combination for a desired AVT and selectivity.

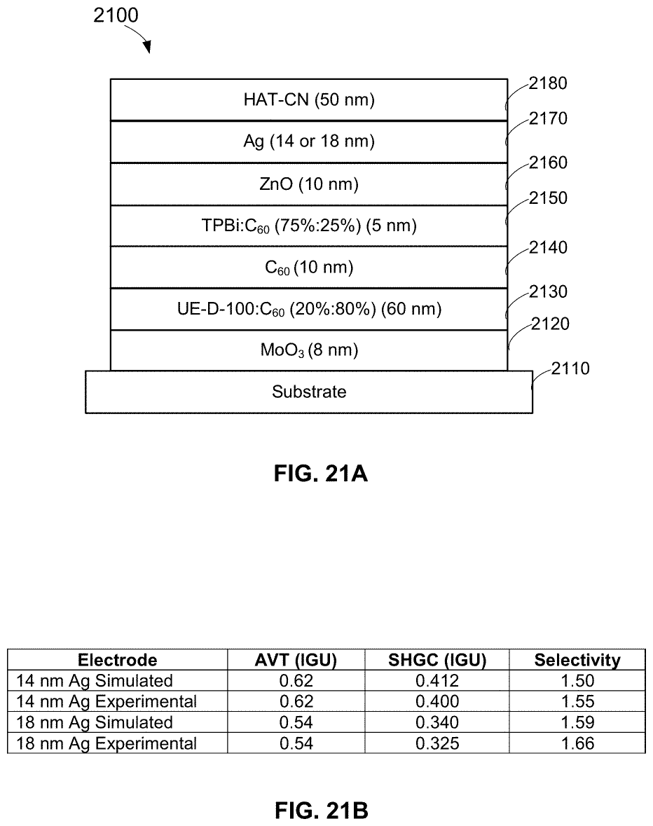

FIG. 21A illustrates examples of TPV devices 2100 each including a transparent AR layer and a metal layer of a different respective thickness according to certain embodiments. TPV devices 2100 may be specific examples of TPV devices 1500. A substrate 2110 may be similar to substrate 1510, and a plurality of layers 2120-2180 formed on substrate 2110 may be similar to layers 1520-1580. For example, layer 2120 of TPV device 2100 may be an HTL layer, such as layer 1520, and may include a thin MoO₃ layer. Layer 2170 of TPV device 2100 may be a silver cathode similar to layer 1570. The thickness of layer 2170 in TPV devices 2100 shown in FIG. 21A may be about 14 nm or about 18 nm. A layer 2160 of TPV device 2100 may include a ZnO layer similar to layer 1560 and may also be used as an ETL layer. The active layers may include a UE-D-100:C₆₀ layer 2130 and a C₆₀ layer 2140, which may be similar to UE-D-100:C₆₀ layer 1530 and C₆₀ layer 1540, respectively. TPBi:C₆₀ layer 2150 may be a buffer layer. Layer 2180 may include an AR layer (e.g., a HAT-CN layer with a thickness 50 nm) for reducing the reflection of visible light at the interface between TPV device 2100 and the ambient environment (e.g. air, Ar, or vacuum).

FIG. 21B illustrates a comparison between the simulated and measured performance of the examples of TPV device 2100 shown in FIG. 21A. Two TPV devices 2100 that each have an AR layer 2180 (comprising a 50-nm HAT-CN layer) and a silver layer of 14 nm or 18 nm were fabricated and measured. As shown in FIG. 21B, the simulated values are in close agreement with the experimental results for both TPV devices 2100.

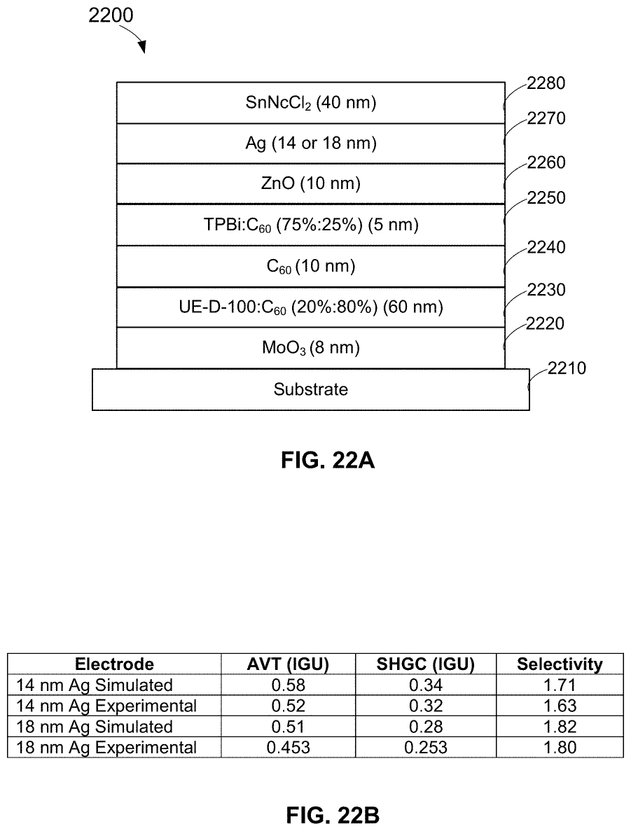

FIG. 22A illustrates examples of TPV devices 2200 each including an NIR absorbing AR layer and a metal layer having a different respective thickness according to certain embodiments. TPV devices 2200 may be specific examples of TPV devices 1600. A substrate 2210 may be similar to substrate 1610, and a plurality of layers 2220-2280 formed on substrate 2210 may be similar to layers 1620-1680. For example, layer 2220 of TPV device 2200 may be an HTL layer, such as layer 1620, and may include a thin MoO₃ layer. Layer 2270 of TPV device 2200 may be a silver cathode similar to layer 1670. The thickness of layer 2270 in TPV devices 2200 shown in FIG. 22A may be about 14 nm or about 18 nm. A layer 2260 of TPV device 2200 may include a ZnO layer similar to layer 1660 and may also be used as an ETL layer. The active layers may include a UE-D-100:C₆₀ layer 2230 and a C₆₀ layer 2240, which may be similar to UE-D-100:C₆₀ layer 1630 and C₆₀ layer 1640, respectively. TPBi:C₆₀ layer 2250 may be a buffer layer. Layer 2280 may include an AR layer (e.g., a SnNcCl₂ layer with a thickness about 40 nm) for reducing the reflection of visible light at the interface between TPV device 2200 and the ambient environment (e.g. air, Ar, or vacuum). SnNcCl₂ in the AR layer may selectively absorb NIR light while transmitting visible light with minimal loss.

FIG. 22B illustrates a comparison between the simulated and measured performance of the examples of TPV devices 2200 shown in FIG. 22A. Two TPV devices 2200 that each include an AR layer 2280 (comprising a 40-nm SnNcCl₂ layer) and silver layer of 14 nm or 18 nm were fabricated and measured. As shown in FIG. 22B, the simulated values are in close agreement with the experimental results for both TPV devices 2200. The experimental results shown FIGS. 21B and 22B also confirm the significant improvement in the SHGC and selectivity using selective NIR absorbing materials.

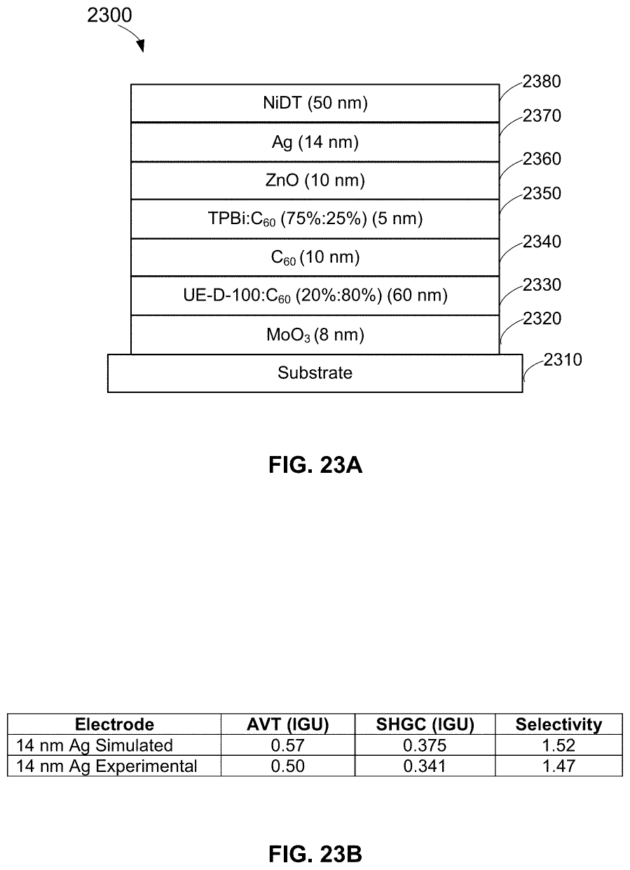

FIG. 23A illustrates an example of a TPV device 2300 including an NIR absorbing AR layer and a metal layer according to certain embodiments. TPV device 2300 may be a specific example of TPV devices 1100. A substrate 2310 may be similar to substrate 1110, and a plurality of layers 2320-2380 formed on substrate 2310 may be similar to layers 1120-1180. For example, layer 2320 of TPV device 2300 may be an HTL layer, such as layer 1120, and may include a thin MoO₃ layer. Layer 2370 of TPV device 2300 may be a silver cathode similar to layer 1170. The thickness of layer 2370 in TPV device 2300 shown in FIG. 23A may be about 14 nm. A layer 2360 of TPV device 2300 may include a ZnO layer similar to layer 1160 and may also be used as an ETL layer. The active layers may include a UE-D-100:C₆₀ layer 2330 and a C₆₀ layer 2340, which may be similar to UE-D-100:C₆₀ layer 1130 and C₆₀ layer 1140, respectively. TPBi:C₆₀ layer 2350 may be a buffer layer. An optical layer 2380 may include an AR layer (e.g., a NiDT layer with a thickness about 50 nm) for reducing the reflection of visible light at the interface between TPV device 2300 and the ambient environment (e.g. air, Ar, or vacuum). NiDT in the AR layer may have a lower NIR extinction as compared to SnNcCl₂, as shown in FIG. 6.

FIG. 23B illustrates a comparison between the simulated and measured performance of the example TPV device 2300 shown in FIG. 23A. A TPV device 2300 with an AR layer 2380 (comprising a 50-nm NiDT layer) and a silver layer of 14 nm was fabricated and measured. As shown in FIG. 23B, the simulated values are in close agreement with the experimental values for TPV device 2300 (with errors less than about 10%). The experimental results shown FIGS. 21B and 23B also confirm that there is negligible selectivity improvement when using NIR absorbing materials that have a low extinction coefficient in the NIR in the AR layer.

The following section describes examples of methods used to determine the AVT, Tₛₒₗ, Aₛₒₗ, and SHGC of TPV devices according certain embodiments.

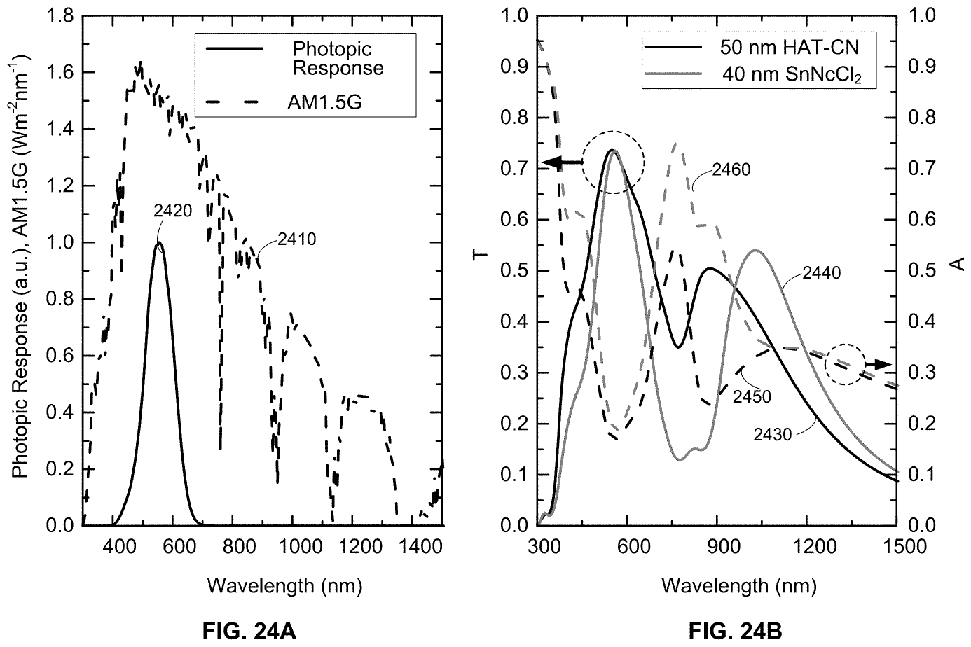

FIG. 24A illustrates the AM1.5G energy flux of the solar spectrum and the photopic response of human eyes. A curve 2410 represents the AM1.5G energy flux of the solar spectrum, which has high energy flux in the visible and the IR bands. A curve 2420 represents the photopic response of human eyes, which has a highest response for green light and lower responses for red and blue light. Curves 2410 and 2420 may be used to calculate the AVT, Tₛₒₗ, Aₛₒₗ, and/or SHGC as described above and below.

FIG. 24B illustrates transmission (T) and absorption (A) spectra of two TPV devices each including an AR layer that includes a 50-nm HAT-CN layer or a 40-nm SnNcCl₂ layer according to certain embodiments. A curve 2430 shows the transmission spectrum of a TPV device with an AR layer that includes a 50-nm HAT-CN layer in device 700. A curve 2440 shows the transmission spectrum of a TPV device with an AR layer that includes a 40-nm SnNcCl₂ layer in device 800. A curve 2450 shows the absorption spectrum of the TPV device with the AR layer that includes the 50-nm HAT-CN layer. A curve 2460 shows the absorption spectrum of the TPV device with the AR layer that includes the 40-nm SnNcCl₂ layer. FIG. 24B shows that the TPV device with the 40-nm SnNcCl₂ layer may have much higher absorption and reduced transmission in the NIR band than the TPV device with the 50-nm HAT-CN layer.

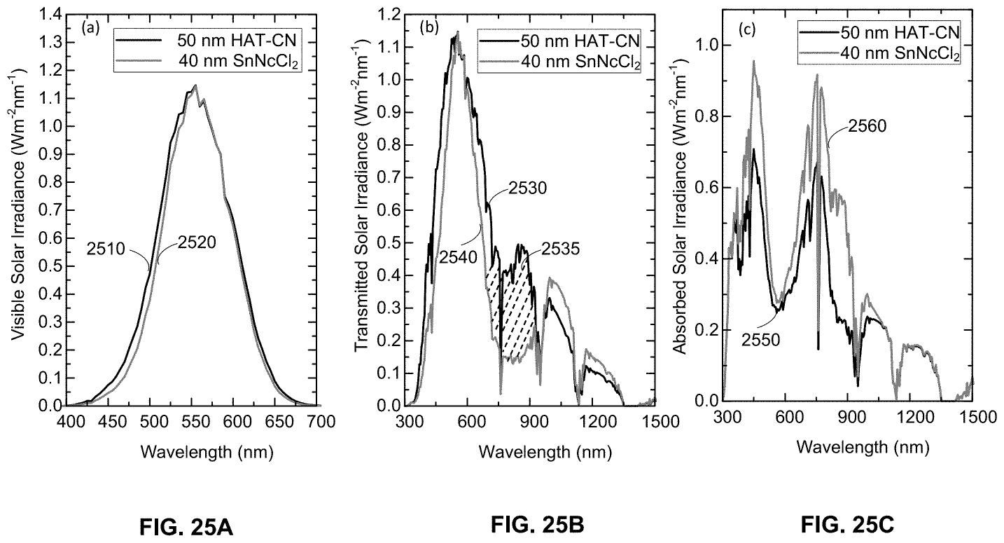

FIG. 25A illustrates visible solar irradiance spectra of two TPV devices each including an AR layer that includes a 50-nm HAT-CN layer or a 40-nm SnNcCl₂ layer according to certain embodiments. The visible solar irradiance spectrum for each device may be determined using a product of the transmission spectrum of the device shown in FIG. 24B, and the AM1.5G spectrum (e.g., curve 2410) and the photopic response (e.g., curve 2420) shown in FIG. 24A. A curve 2510 shows the visible solar irradiance spectrum of the TPV device with the AR layer that includes the 50-nm HAT-CN layer. A curve 2520 shows the visible solar irradiance spectrum of the TPV device with the AR layer that includes the 40-nm SnNcCl₂ layer.

FIG. 25B illustrates transmitted solar irradiance of two TPV devices each including a 50 nm HAT-CN layer or a 40 nm SnNcCl₂ AR layer, according to certain embodiments. The transmitted solar irradiance may be calculated as the product of the transmission spectrum of the device shown in FIG. 24B, and the AM1.5G energy flux of the solar spectrum shown in FIG. 24A. A curve 2530 in FIG. 25B shows the transmitted solar irradiance of the TPV device with the 50-nm HAT-CN AR layer. A curve 2540 shows the transmitted solar irradiance of the TPV device with the 40-nm SnNcCl₂ layer AR layer. As shown by a shaded area 2535, the transmitted solar irradiance of the TPV device with the 40-nm SnNcCl₂ layer is significantly reduced for NIR light with wavelengths between about 700 nm and about 900 nm due to the selective absorption by SnNcCl₂.

FIG. 25C illustrates absorbed solar irradiance of two TPV devices each including a 50-nm HAT-CN layer or a 40-nm SnNcCl₂ AR layer, according to certain embodiments. The absorbed solar irradiance may be calculated as the product of the absorption spectrum shown in FIG. 24B and the AM1.5G energy flux of the solar spectrum shown in FIG. 24A. A curve 2550 in FIG. 25C shows the absorbed solar irradiance of the TPV device with the 50 nm HAT-CN AR layer. A curve 2560 shows the absorbed solar irradiance of the TPV device with the 40 nm SnNcCl₂ AR layer. As shown in FIG. 25C, in a wavelength range from about 700 nm to about 900 nm, the absorbed solar irradiance of the TPV device with the 40 nm SnNcCl₂ layer is significantly higher than the TPV device with the 50 nm HAT-CN layer due to the selective absorption by SnNcCl₂.

Solar transmittance (Tₛₒₗ) is calculated by normalizing the integral of transmitted solar irradiance to the integral of AM1.5D spectral irradiance. Solar absorptance (Aₛₒₗ) is calculated by normalizing the integral of absorbed solar irradiance to the integral of AM1.5D spectral irradiance. To determine the SHGC, the Aₛₒₗ may be multiplied by N (e.g., about 0.1) and summed with Tₛₒₗ according to SHGC=Tₛₒₗ+Aₛₒₗ×N. As a result, the SHGC of the TPV device with the 40 nm SnNcCl₂ layer may decrease due to a decrease in Tₛₒₗ at a higher rate than Aₛₒₗ may increase (due to the factor N).

The selective near-IR absorbing materials may also be used to improve the SHGC and selectivity of IGUs that may not include transparent photovoltaic devices, such as in standard window coatings. Low emissivity (low-e) window coatings may generally include thin silver layers sandwiched between non-absorbing dielectric layers, such as certain oxides, deposited on the surface of the glass. The silver layers may preferentially reflect light in the NIR, while partially transmitting visible light. In a coating that includes a silver layer sandwiched by two dielectric layers, the thicknesses of the dielectric layers may be tuned such that dielectric layers may function as an AR layer for visible light. Two or more silver layers may also be separated by dielectric layers in a window coating, such that an optical cavity may be formed and tuned to reduce the NIR transmission while selectively allowing visible light to pass through.

According to certain embodiments, using a selective NIR absorbing material in such low-e coatings can help achieve improved selectivity over those using more transparent dielectric (e.g. oxides) layers. For example, in a coating including a thin silver film sandwiched between two zinc oxide (ZnO) layers, one or both of the ZnO layers can be replaced with a selective NIR absorbing material, such as SnNcCl₂.

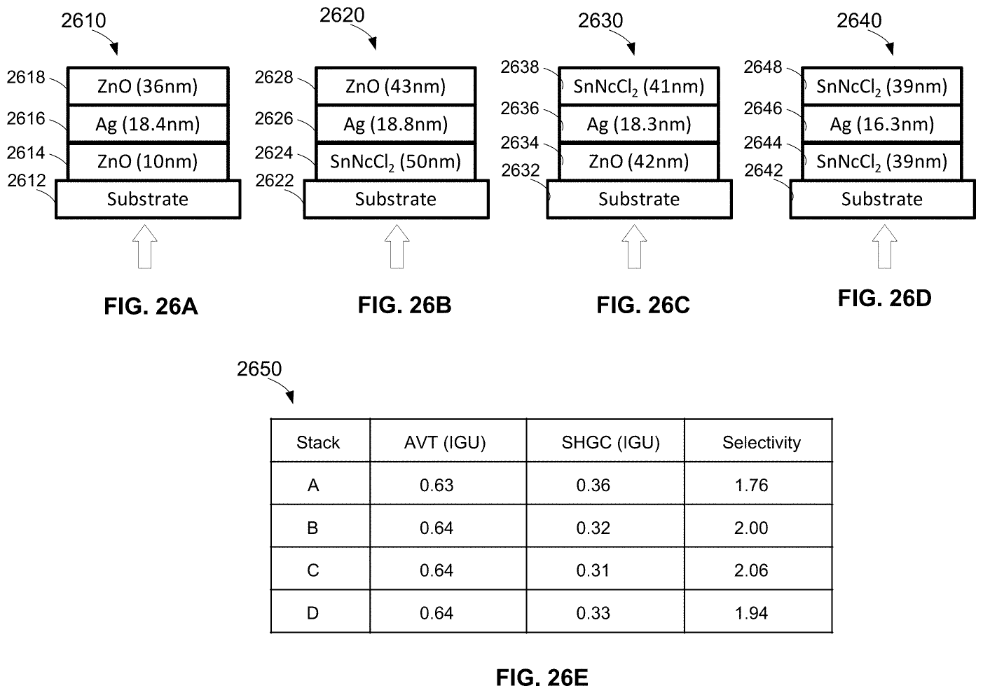

FIG. 26A illustrates an example of a low-e coating structure 2610 that includes a thin silver layer 2616 sandwiched between two ZnO layers 2614 and 2618. In the illustrated example, low-e coating structure 2610 includes a substrate 2612, which may be similar to, for example, substrates 510, 710, 810, 910, 1010, and the like described above. First ZnO layer 2614 may be coated on substrate 2612, a thin silver layer 2616 may be coated on first ZnO layer 2614, and second ZnO layer 2618 may be coated on thin silver layer 2616. Thin silver layer 2616 may preferentially reflect light in the NIR band, while at least partially transmitting visible light. The thicknesses of ZnO layers 2614 and 2618 and thin silver layer 2616 shown in FIG. 26A are optimized for best selectivity.

FIG. 26B illustrates an example of a low-e coating structure 2620 in which a SnNcCl₂ layer 2624 replaces the first ZnO layer 2614 of low-e coating structure 2610 shown in FIG. 26A according to certain embodiments. In the example illustrated in FIG. 26B, low-e coating structure 2620 includes a substrate 2622, which may be similar to substrate 2612 of FIG. 26A. SnNcCl₂ layer 2624 may be coated on substrate 2622, a thin silver layer 2626 may be coated on SnNcCl₂ layer 2624, and a ZnO layer 2628 may be coated on thin silver layer 2626. Thin silver layer 2626 may preferentially reflect light in the NIR band, while at least partially transmitting visible light. The thicknesses of SnNcCl₂ layer 2624, ZnO layers 2628, and thin silver layer 2626 shown in FIG. 26B are optimized for best selectivity.

FIG. 26C illustrates an example of a low-e coating structure 2630 in which a SnNcCl₂ layer 2638 replaces the second ZnO layer 2618 of low-e coating structure 2610 according to certain embodiments. In the example illustrated in FIG. 26C, low-e coating structure 2630 includes a substrate 2632, which may be similar to substrate 2612 of FIG. 26A. A ZnO layer 2634 may be coated on substrate 2632, a thin silver layer 2636 may be coated on ZnO layer 2634, and SnNcCl₂ layer 2638 may be coated on thin silver layer 2636. Thin silver layer 2636 may preferentially reflect light in the NIR band, while at least partially transmitting visible light. The thicknesses of SnNcCl₂ layer 2638, ZnO layers 2634, and thin silver layer 2636 shown in FIG. 26C are optimized for best selectivity.

FIG. 26D illustrates an example of a low-e coating structure 2640 in which SnNcCl₂ layers 2644 and 2648 replace ZnO layers 2614 and 2618 of low-e coating structure 2610 according to certain embodiments. In the example illustrated in FIG. 26D, low-e coating structure 2640 includes a substrate 2642, which may be similar to substrate 2612 of FIG. 26A. First SnNcCl₂ layer 2644 may be coated on substrate 2642, a thin silver layer 2646 may be coated on first SnNcCl₂ layer 2644, and second SnNcCl₂ layer 2648 may be coated on thin silver layer 2646. Thin silver layer 2646 may preferentially reflect light in the NIR band, while at least partially transmitting visible light. The thicknesses of first SnNcCl₂ layer 2644, second SnNcCl₂ layer 2648, and thin silver layer 2646 shown in FIG. 26D are optimized for best selectivity.

FIG. 26E includes a table 2650 illustrating simulated performance of examples of low-e coating structures 2610-2640 shown in FIGS. 26A-26D according to certain embodiments. As shown in table 2650, the layer stack illustrated in FIG. 26A (referred to as Stack A), which includes two oxide dielectric layers, shows the lowest selectivity. Each of the layer stacks that include an selective absorber, such as the layer stack shown in FIG. 26B (referred to as Stack B), the layer stack shown in FIG. 26C (referred to as Stack C), and the layer stack shown in FIG. 26D (referred to as Stack D), shows improved selectivity (e.g., close to or greater than about 2.0) while maintaining high AVT.

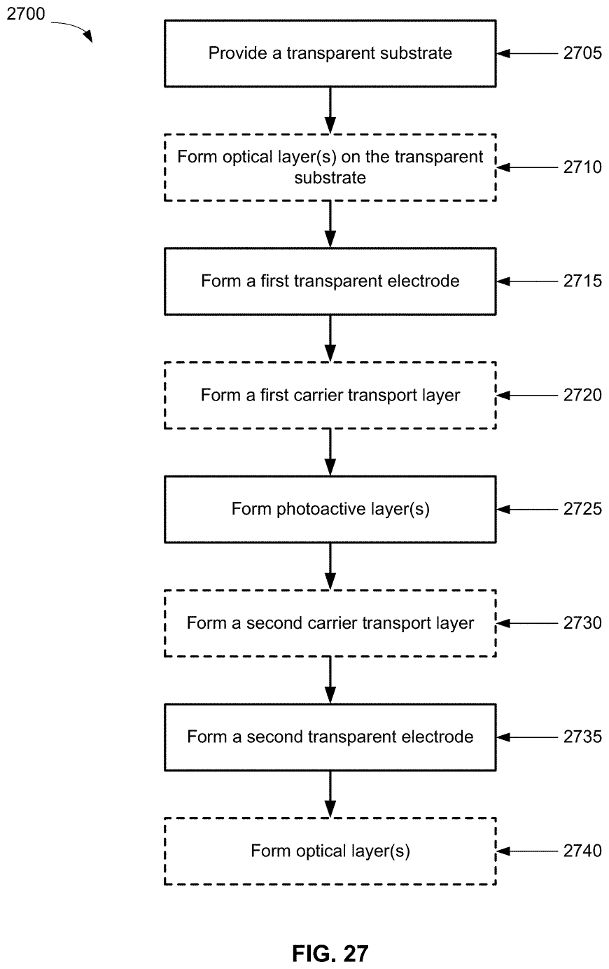

FIG. 27 is a simplified flow chart 2700 illustrating an example of a method for manufacturing a TPV device according to certain embodiments. Flow chart 2700 may begin at block 2705, where a transparent substrate is provided. It will be appreciated that useful transparent substrates may include visibly transparent substrates, such as glass, plastic, quartz, and the like. Flexible and rigid substrates are useful with various embodiments. Optionally, the transparent substrate is provided with one or more optical layers applied on top and/or bottom surfaces.

At block 2710, one or more optical layers are optionally formed on or over the transparent substrate, such as on top and/or bottom surfaces of the transparent substrate. Optionally, one or more optical layers are formed on other materials, such as an intervening layer or material, such as a transparent conductor. Optionally, one or more optical layers are positioned adjacent to and/or in contact with the visibly transparent substrate. It will be appreciated that the formation of the optical layers is optional, and some embodiments may not include optical layers adjacent to and/or in contact with the transparent substrate. Optical layers may be formed using a variety of methods including, but not limited to, one or more chemical deposition methods, such as plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. It will be appreciated that useful optical layers include visibly transparent optical layers. Useful optical layers include those that provide one or more optical properties including, for example, antireflection properties, wavelength selective reflection or distributed Bragg reflection properties, index matching properties, encapsulation, or the like. Useful optical layers may optionally include optical layers that are transparent to ultraviolet and/or near-infrared light. Depending on the configuration, however, some optical layers may optionally provide passive infrared and/or ultraviolet absorption. For example, in some embodiments, a thin layer of a selective NIR absorbing material, such as SnNcCl₂, SnNc, BBT, and the like, may be formed in the optical layer(s) using various deposition techniques described above. The thickness of the layer of the selective NIR absorbing material may be selected based on the desired AVT, SHGC, and/or selectivity of the TPV device.

At block 2715, a first transparent electrode is formed. As described above, the first transparent electrode may be an anode, and may include an ITO film, an FTO film, or other transparent conducting films, such as thin metal films (e.g., Ag, Cu, etc.), multilayer stacks comprising thin metal films (e.g., Ag, Cu, etc.) and dielectric materials, or conductive organic materials (e.g., conducting polymers, etc.). It will be appreciated that transparent electrodes include visibly transparent electrodes. Transparent electrodes may be formed using one or more deposition processes, including vacuum deposition techniques, such as atomic layer deposition, chemical vapor deposition, physical vapor deposition, thermal evaporation, sputter deposition, epitaxy, and the like. Solution based deposition techniques, such as spin-coating, may also be used in some cases. In addition, transparent electrodes may be patterned by way of microfabrication techniques, such as lithography, lift off, etching, and the like.

At block 2720, a first carrier transport layer, such as a hole transport layer, may optionally be formed, for example, on the first transparent electrode. The hole transport layer may include, for example, MoO₃, WO₃, NiOx, or V₂O₅, and may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition. In some embodiments, the first carrier transport layer may also include, for example, electron blocking layers, optical spacers, physical buffer layers, charge recombination layers, or charge generation layers. In some embodiments, a thin layer of a selective NIR absorbing material, such as SnNcCl₂, SnNc, BBT, and the like, may be formed in the first carrier transport layer using various deposition techniques described above. The thickness of the layer of the selective NIR absorbing material may be selected based on the desired AVT, SHGC, and/or selectivity of the TPV device.

At block 2725, one or more photoactive layers are formed, for example, on a carrier transport layer or on a transparent electrode. As described above, photoactive layers may include electron acceptor layers and electron donor layers or co-deposited layers of electron donors and acceptors (e.g., UE-D-100:C₆₀ or TPBi:C₆₀). Useful photoactive layers include those comprising the visibly transparent photoactive compounds described herein. As described above, in some embodiments, a thin layer of a selective NIR absorbing material, such as SnNcCl₂, SnNc, BBT, and the like, may be formed in the photoactive layers using various deposition techniques described above. The thickness of the layer of the selective NIR absorbing material may be selected based on the desired AVT, SHGC, and/or selectivity of the TPV device. The photoactive layers may be formed using a variety of methods including, but not limited to, one or more chemical deposition methods, such as a plating, chemical solution deposition, spin coating, dip coating, chemical vapor deposition, plasma enhanced chemical vapor deposition, and atomic layer deposition, or one or more physical deposition methods, such as thermal evaporation, electron beam evaporation, molecular beam epitaxy, sputtering, pulsed laser deposition, ion beam deposition, and electrospray deposition.

In some examples, visibly transparent photoactive compounds useful for photoactive layers may be deposited using a vacuum deposition technique, such as thermal evaporation. Vacuum deposition may take place in a vacuum chamber, such as at pressures of between about 10⁻⁵ Torr and about 10⁻⁸ Torr. In one example, vacuum deposition may take place at a pressure of about 10⁻⁷ Torr. As noted above, various deposition techniques may be applied. In some embodiments, thermal evaporation is used. Thermal evaporation may include heating a source of the material (i.e., the visibly transparent photoactive compound) to be deposited to a temperature of between 200° C. and 2700° C. The temperature of the source of material may be selected to achieve a thin film growth rate of between about 0.01 nm/s and about 1 nm/s. For example, a thin film growth rate of 0.1 nm/s may be used. These growth rates are useful to generate thin films having thicknesses of between about 1 nm and 2700 nm over the course of minutes to hours. It will be appreciated that various properties (e.g., the molecular weight, volatility, thermal stability) of the material being deposited may dictate or influence the source temperature or maximum useful source temperature. For example, a thermal decomposition temperature of the material being deposited may limit the maximum temperature of the source. As another example, a material being deposited that is highly volatile may require a lower source temperature to achieve a target deposition rate as compared to a material that is less volatile, where a higher source temperature may be needed to achieve the target deposition rate. As the material being deposited is evaporated from the source, it may be deposited on a surface (e.g., substrate, optical layer, transparent electrode, buffer layer, etc.) at a lower temperature. For example, the surface may have a temperature from about 10° C. to about 100° C. In some cases, the temperature of the surface may be actively controlled. In some cases, the temperature of the surface may not be actively controlled.

At block 2730, a second carrier transport layer, such as an electron transport layer, may optionally formed, for example, on the photoactive layer(s). The second carrier transport layer may include, for example, ZnO, In₂O₃, SnO₂, TiO₂, AZO, FTO, Al:MoO₃, BaSnO₃, or the like, and may be formed similar to the first carrier transport layer formed at block 2720. In some embodiments, the second carrier transport layer may also include, for example, holes blocking layers, optical spacers, physical buffer layers, charge recombination layers, or charge generation layers. In some embodiments, a thin layer of a selective NIR absorbing material, such as SnNcCl₂, SnNc, BBT, and the like, may be formed in the second carrier transport layer using various deposition techniques described above. The thickness of the layer of the selective NIR absorbing material may be selected based on the desired AVT, SHGC, and/or selectivity of the TPV device. In addition, it will be appreciated that operations at blocks 2720, 2725, and 2730 may be repeated one or more times, such as to form a multilayer stack of materials including a photoactive layer and, optionally, various carrier transport layers.

At block 2735, a second transparent electrode may be formed, for example, on a carrier transport layer or on a photoactive layer. The second transparent electrode may be formed using techniques applicable to the formation of the first transparent electrode at block 2715.

At block 2740, one or more optical layers may optionally be formed, such as on the second transparent electrode. As described above, in some embodiments, the optical layer may include a layer of a selective NIR absorbing material, such as SnNcCl₂, SnNc, BBT, and the like. The thickness of the layer of the selective NIR absorbing material may be selected based on the desired AVT, SHGC, and/or selectivity of the TPV device.

It should be appreciated that the specific steps illustrated in FIG. 27 provide a particular method of making a visibly transparent photovoltaic device according to various embodiments of the present invention. Other sequences of steps may also be performed according to alternative embodiments. For example, alternative embodiments of the present invention may perform the steps outlined above in a different order. Moreover, the individual steps illustrated in FIG. 27 may include multiple sub-steps that may be performed in various sequences as appropriate to the individual step. Furthermore, additional steps may be added or removed depending on the particular applications. It will be appreciated that many variations, modifications, and alternatives may be used.

The method shown by FIG. 27 may optionally be extended to a method for generating electrical energy. For example, a method for generating electrical energy may comprise providing a visibly transparent photovoltaic device, such as by making a visibly transparent photovoltaic device according to the method. Methods for generating electrical energy may further comprise exposing the visibly transparent photovoltaic device to visible, ultraviolet and/or near-infrared light to drive the formation and separation of electron-hole pairs, as described above, for example, for generation of electrical energy. The visibly transparent photovoltaic device may include the visibly transparent photoactive compounds described herein as photoactive materials, buffer materials, and/or optical layers.

All references throughout this disclosure, for example patent documents including issued or granted patents or equivalents; patent application publications; and non-patent literature documents or other source material; are hereby incorporated by reference herein in their entireties, as though individually incorporated by reference.

All patents and publications mentioned in this disclosure are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a compound is claimed, it should be understood that compounds known in the prior art, including certain compounds disclosed in the references disclosed herein (particularly in referenced patent documents), are not intended to be included in the claim.

When a group of substituents is disclosed herein, it is understood that all individual members of those groups and all subgroups and classes that can be formed using the substituents are disclosed separately. When a Markush group or other grouping is used herein, all individual members of the group and all combinations and sub-combinations possible of the group are intended to be individually included in the disclosure. As used herein, “and/or” means that one, all, or any combination of items in a list separated by “and/or” are included in the list; for example “1, 2 and/or 3” is equivalent to “‘1’ or ‘2’ or ‘3’ or ‘1 and 2’ or ‘1 and 3’ or ‘2 and 3’ or 1, ‘2 and 3’”.

Every formulation or combination of components described or exemplified can be used to practice the invention, unless otherwise stated. Specific names of materials are intended to be exemplary, as it is known that one of skill in the art can name the same material differently. It will be appreciated that methods, device elements, starting materials, and synthetic methods other than those specifically exemplified can be employed in the practice of the invention without resort to undue experimentation. All art-known functional equivalents, of any such methods, device elements, starting materials, and synthetic methods are intended to be included in this invention. Whenever a range is given in the specification, for example, a temperature range, a time range, or a composition range, all intermediate ranges and subranges, as well as all individual values included in the ranges given are intended to be included in the disclosure.

As used herein, “comprising” is synonymous with “including,” “containing,” “having,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

As used herein, the terms “a,” “an,” “the,” and similar referents in the context of describing the disclosed embodiments (especially in the context of the following claims) are to be construed to cover both the singular and the plural, unless otherwise indicated herein or clearly contradicted by context. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein and each separate value is incorporated into the specification as if it were individually recited herein. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is intended to be understood within the context as used in general to present that an item, term, and the like, may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered within the scope of this invention as defined by the appended claims.

What is claimed is:

1. A visibly transparent photovoltaic device comprising:
a visibly transparent substrate;
a first visibly transparent electrode on the visibly transparent substrate;
a second electrode;
a visibly transparent photoactive layer between the first visibly transparent electrode and the second electrode, the visibly transparent photoactive layer configured to convert at least one of near-infrared light or ultraviolet light into photocurrent; and
a near-infrared absorbing material layer configured to absorb the near-infrared light and transmit visible light.

2. The visibly transparent photovoltaic device of claim 1, wherein the near-infrared absorbing material layer is characterized by a peak extinction coefficient at a wavelength longer than 650 nm.

3. The visibly transparent photovoltaic device of claim 2, wherein the peak extinction coefficient is greater than 0.4.

4. The visibly transparent photovoltaic device of claim 2, wherein the near-infrared absorbing material layer includes SnNcCl₂, SnNc, or BBT.

5. The visibly transparent photovoltaic device of claim 1, wherein the near-infrared absorbing material layer includes an antireflection layer for the visible light.

6. The visibly transparent photovoltaic device of claim 5, wherein the antireflection layer is on the visibly transparent substrate or the second electrode.

7. The visibly transparent photovoltaic device of claim 1, wherein the near-infrared absorbing material layer is in the visibly transparent photoactive layer.

8. The visibly transparent photovoltaic device of claim 1, further comprising a hole transport layer, wherein the near-infrared absorbing material layer is in the hole transport layer.

9. The visibly transparent photovoltaic device of claim 8, wherein the hole transport layer includes at least one of MoO₃, WO₃, NiOx, ITO, or V₂O₅.

10. The visibly transparent photovoltaic device of claim 1, further comprising an electron transport layer, wherein the near-infrared absorbing material layer is in the electron transport layer.

11. The visibly transparent photovoltaic device of claim 10, wherein the electron transport layer includes at least one of ZnO, In₂O₃, SnO₂, TiO₂, AZO, FTO, Al:MoO₃, or BaSnO₃.

12. The visibly transparent photovoltaic device of claim 1, further comprising an antireflection layer, a hole transport layer, and an electron transport layer, wherein the near-infrared absorbing material layer is in at least one of the antireflection layer, the hole transport layer, the electron transport layer, or the visibly transparent photoactive layer.

13. The visibly transparent photovoltaic device of claim 1, wherein the second electrode is configured to at least partially reflect the near-infrared light.

14. The visibly transparent photovoltaic device of claim 13, wherein the second electrode includes a silver layer characterized by a thickness equal to or less than 20 nm.

15. The visibly transparent photovoltaic device of claim 1, wherein the near-infrared absorbing material layer is characterized by a thickness less than 60 nm.

16. The visibly transparent photovoltaic device of claim 1, wherein the visibly transparent photovoltaic device is characterized by an average visible transmittance equal to or greater than 0.45.

17. The visibly transparent photovoltaic device of claim 1, wherein the visibly transparent photovoltaic device is characterized by a selectivity equal to or greater than 1.5.

18. A window panel comprising:
a visibly transparent substrate;
a first visibly transparent dielectric layer on the visibly transparent substrate;
a near-infrared reflection layer on the first visibly transparent dielectric layer and configured to at least partially reflect near-infrared light; and
a second visibly transparent dielectric layer on the near-infrared reflection layer,
wherein at least one of the first visibly transparent dielectric layer or the second visibly transparent dielectric layer includes a near-infrared absorbing material configured to absorb the near-infrared light and transmit visible light.

19. The window panel of claim 18, wherein the near-infrared absorbing material includes at least one of SnNcCl₂, SnNc, or BBT.

20. The window panel of claim 18, wherein the near-infrared reflection layer includes a silver layer.
